(19) United States
(12) Patent Application Publication
(10) Pub. No.: US 2026/0122924 A1
(43) Pub. Date: Apr. 30, 2026

(54) MEMORY DEVICES WITH DIODES AND METHODS FOR MANUFACTURING THE SAME

(71) Applicant: Taiwan Semiconductor Manufacturing Company, Ltd., Hsinchu (TW)

(72) Inventors: Chia-En Huang, Hsinchu City (TW); Tzu-Yu Chen, Hsinchu City (TW)

(73) Assignee: Taiwan Semiconductor Manufacturing Company, Ltd., Hsinchu (TW)

(21) Appl. No.: 18/930,739

(22) Filed: Oct. 29, 2024

(51) Int. Cl. H10B 99/00

(52) U.S. Cl. CPC H10B 99/16

(57) ABSTRACT

A memory device includes a well formed in a substrate and extending along a first lateral direction, wherein the well has a first conductive type. The memory device includes a plurality of epitaxial structures disposed over the well, wherein the plurality of epitaxial structures have a second conductive type opposite to the first conductive type. The memory device includes a common epitaxial structure disposed over the well, wherein the common epitaxial structure has the first conductive type and is in contact the well. A first group of the plurality of epitaxial structures are each in contact with the well, and a second group of the plurality of epitaxial structures each have a bottom surface separated from the well with a corresponding dielectric layer.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a read only memory (ROM) cell, in accordance with some embodiments.

FIG. 2 illustrates another schematic diagram of a read only memory (ROM) cell, in accordance with some embodiments.

FIG. 3 illustrates a layout for forming a memory array including a plural number of ROM cells, in accordance with some embodiments.

FIG. 4 illustrates a hybrid cross-sectional view of a memory array formed based on the layout of FIG. 3, in accordance with some embodiments.

FIG. 5 and FIG. 6 illustrate cross-sectional views of the memory array shown in FIG. 4, respectively, in accordance with some embodiments.

FIG. 7 illustrates a layout for forming a memory array including a plural number of ROM cells, in accordance with some embodiments.

FIG. 8 illustrates a hybrid cross-sectional view of a memory array formed based on the layout of FIG. 7, in accordance with some embodiments.

FIG. 9 and FIG. 10 illustrate cross-sectional views of the memory array shown in FIG. 8, respectively, in accordance with some embodiments.

FIG. 11 illustrates a layout for forming a memory array including a plural number of ROM cells, in accordance with some embodiments.

FIG. 12 illustrates a hybrid cross-sectional view of a memory array formed based on the layout of FIG. 11, in accordance with some embodiments.

FIG. 13 and FIG. 14 illustrate cross-sectional views of the memory array shown in FIG. 12, respectively, in accordance with some embodiments.

FIG. 15 illustrates a layout for forming a memory array including a plural number of ROM cells, in accordance with some embodiments.

FIG. 16 illustrates a hybrid cross-sectional view of a memory array formed based on the layout of FIG. 15, in accordance with some embodiments.

FIG. 17 and FIG. 18 illustrate cross-sectional views of the memory array shown in FIG. 4, respectively, in accordance with some embodiments.

FIG. 19 illustrates a layout for forming a memory array including a plural number of ROM cells, in accordance with some embodiments.

FIG. 20 illustrates a hybrid cross-sectional view of a memory array formed based on the layout of FIG. 19, in accordance with some embodiments.

FIG. 21 and FIG. 22 illustrate cross-sectional views of the memory array shown in FIG. 20, respectively, in accordance with some embodiments.

FIG. 23 illustrates a layout for forming a memory array including a plural number of ROM cells, in accordance with some embodiments.

FIG. 24 illustrates a hybrid cross-sectional view of a memory array formed based on the layout of FIG. 23, in accordance with some embodiments.

FIG. 25 and FIG. 26 illustrate cross-sectional views of the memory array shown in FIG. 24, respectively, in accordance with some embodiments.

FIG. 27 illustrates a layout for forming a memory array including a plural number of ROM cells, in accordance with some embodiments.

FIG. 28 illustrates a hybrid cross-sectional view of a memory array formed based on the layout of FIG. 27, in accordance with some embodiments.

FIG. 29 illustrates an example flow chart of a method for fabricating a memory array with a plural number of ROM cells, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Read only memory (ROM) arrays are semiconductor memory chip arrays with data permanently stored in the array. ROM arrays are made up of a number of ROM cells, each ROM cell including a semiconductor device (e.g., a transistor, a switch, etc.) that can be configured (e.g., programmed) in an “on” or “off” state. Each ROM cell is configured to store a (e.g., binary) data bit reflecting that on or off state. To program a ROM cell to an on state or an off state, it generally depends on whether a contact via structure connecting an active region (e.g., a source/drain region) of the transistor to an interconnect structure carrying a ground voltage (e.g., VSS) is formed. Accordingly, a ROM array, which include a plural number of ROM cells, can include a plural number of places where no contact via structures are formed. Such an “uneven” distribution of the contact via structures typically causes manufacturing issues. Thus, the existing ROM devices/arrays have not been entirely satisfactory in certain aspects.

The present disclosure provides various embodiments of a memory device (e.g., a memory array) including a plural number of ROM cells. Each of the ROM cells can be formed as a diode based on a transistor-like structure and programmed through various processing techniques. With the ROM cells programmed upon being formed, a relatively uniform distribution of contact via structures can be formed across the memory array, which advantageously avoids the above-identified manufacturing issues. For example, after forming a well (e.g., with a first conductive type) in a substrate, an active region can be formed over the well, which may have the same lengthwise direction as the well. Next, a number of gate structures can be formed to traverse the active region, followed by a number of epitaxial structures formed in the active region to alternately arrange with the gate structures. Prior forming the epitaxial structures, one or more portions of the well can each be covered a dielectric layer. At least a first one of the epitaxial structures, having the first conductive type, can be formed to directly contact the well; at least a second one of the epitaxial structures, having a second, opposite conductive type, can be formed to directly contact the well; and at least a third one of the epitaxial structures, having the second conductive type, can be formed over the corresponding dielectric layer (e.g., physically and electrically separated from the well by the dielectric layer). With the same (first) conductive type, the first epitaxial structure can be formed as a contact or connector coupled to the well. Next, a number of first via structures and a number of second via structure can be formed to contact the gate structures and the epitaxial structures, respectively.

Each of the first via structures, coupled to the respective gate structure, is coupled to a supply voltage (e.g., VDD, VSS) so as to electrically turn off the corresponding transistor, depending on its conductive type. As a non-limiting example, the VDD is around 0.75V and the VSS is around OV. One of the second via structures, coupled to the first epitaxial structure then to the well, is coupled to a common bit line (BL), while the rest of the second via structures, respectively coupled to the second or third epitaxial structures, are each coupled to a respective word line (WL). Accordingly, the first epitaxial structure and the second epitaxial structure can operatively form a “connected diode,” and the first epitaxial structure and the third epitaxial structure can operatively form a “disconnected” diode.” As herein disclosed in the present disclosure, the term “disconnected diode” refers to a diode having a first terminal connected to a corresponding WL and a second terminal connected to a common BL, where the BL and the WL are disconnected from each other; and the term “connected diode” refers to a diode having a first terminal connected to a corresponding WL and a second terminal connected to a common BL, wherein the BL and the WL are coupled to each other. Consequently, upon being formed, the connected diode can be programmed with a first logic state, and the disconnected diode can be programmed with a second logic state.

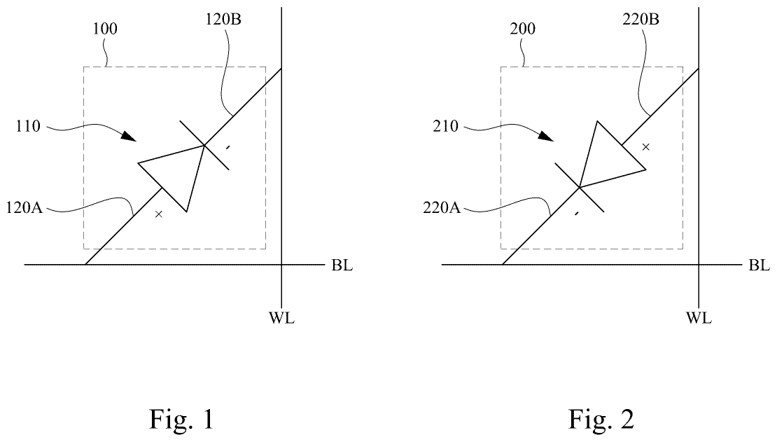

FIG. 1 illustrates an example circuit diagram of a single ROM cell 100, in accordance with some embodiments. A plural number of such ROM cells 100 can be arranged as a (e.g., two-dimensional) array having a plural number of rows and a plural number of columns. Each of the ROM cells is disposed at an intersection of a corresponding one of the rows and a corresponding one of the columns. Each row can correspond to a respective bit line (BL), and each column can correspond to a respective word line (WL). Although the ROM cell 100 shown in FIG. 1 includes one diode, it should be understood that the circuit diagram of FIG. 1 is provided for illustrative purposes and is not intended to limit the scope of the present disclosure. Accordingly, the ROM cell 100 shown in FIG. 1 can include any of various other components, while remaining within the scope of the present disclosure.

As shown, the ROM cell 100 includes one diode 110 having a first terminal 120A and a second terminal 120B. The first terminal 120A and the second terminal 120B can correspond to a positive terminal (anode) and a negative terminal (cathode) of the diode 110, respectively. In some embodiments, the positive (first) terminal 120A, which is formed as a first epitaxial structure, is connected to the bit line BL, and the negative (second) terminal 120B, which is formed a second epitaxial structure, is connected to the word line WL.

In some embodiments of the present disclosure, the bit line BL and the word line WL can be coupled to or decoupled from each other through selectively coupling the respective first and second epitaxial structures to each other. In some embodiments, the bit line BL and the word line WL can be coupled to or decoupled from each other through selectively forming a VD between the word line WL and the positive terminal 120A. In some embodiments, the bit line BL and the word line WL can be coupled to or decoupled from each other through selectively forming a V0 between the word line WL and an M0 track connected to the positive terminal 120A. Whether the ROM cell 100 is in a logical “1” or “0” state can depend on whether the bit line BL and the word line WL of the diode 110 are connected to each other. Stated another way, the ROM cell 100 can be programmed with a logic state, which depends on whether the diode 110 is formed as connected or disconnected. For example, when the word line WL is connected to the bit line BL, the ROM cell 100 presents a logical 1; and when the word line WL is disconnected from the bit line BL, the ROM cell 100 presents a logical 0.

FIG. 2 illustrates an example circuit diagram of a single ROM cell 200, in accordance with some embodiments. A plural number of such ROM cells 200 can be arranged as a (e.g., two-dimensional) array having a plural number of rows and a plural number of columns. Each of the ROM cells is disposed at an intersection of a corresponding one of the rows and a corresponding one of the columns. Each row can correspond to a respective bit line (BL), and each column can correspond to a respective word line (WL). Although the ROM cell 200 shown in FIG. 2 includes one diode, it should be understood that the circuit diagram of FIG. 2 is provided for illustrative purposes and is not intended to limit the scope of the present disclosure. Accordingly, the ROM cell 200 shown in FIG. 2 can include any of various other components, while remaining within the scope of the present disclosure.

As shown, the ROM cell 200 includes one diode 210 having a first terminal 220A and a second terminal 220B. The first terminal 220A and the second terminal 220B can correspond to a negative terminal (cathode) and a positive terminal (anode) of the diode 210, respectively. In some embodiments, the negative (first) terminal 220A, which is formed as a first epitaxial structure, is connected to the bit line BL, and the positive (second) terminal 220B, which is formed a second epitaxial structure, is connected to the word line WL.

In some embodiments of the present disclosure, the bit line BL and the word line WL can be coupled to or decoupled from each other through selectively coupling the respective first and second epitaxial structures to each other. In some embodiments, the bit line BL and the word line WL can be coupled to or decoupled from each other through selectively forming a VD between the word line WL and the negative terminal 220A. In some embodiments, the bit line BL and the word line WL can be coupled to or decoupled from each other through selectively forming a V0 between the word line WL and an M0 track connected to the negative terminal 220A. Whether the ROM cell 200 is in a logical “1” or “0” state can depend on whether the bit line BL and the word line WL of the diode 210 are connected to each other. Stated another way, the ROM cell 200 can be programmed with a logic state, which depends on whether the diode 210 is formed as connected or disconnected. For example, when the word line WL is connected to the bit line BL, the ROM cell 200 presents a logical 1; and when the word line WL is disconnected from the bit line BL, the ROM cell 200 presents a logical 0.

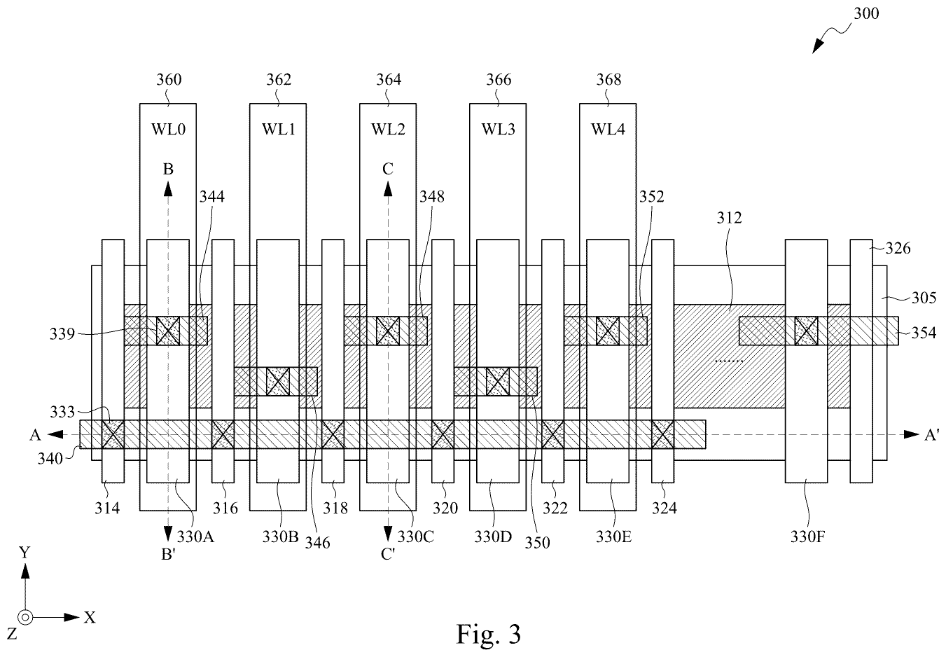

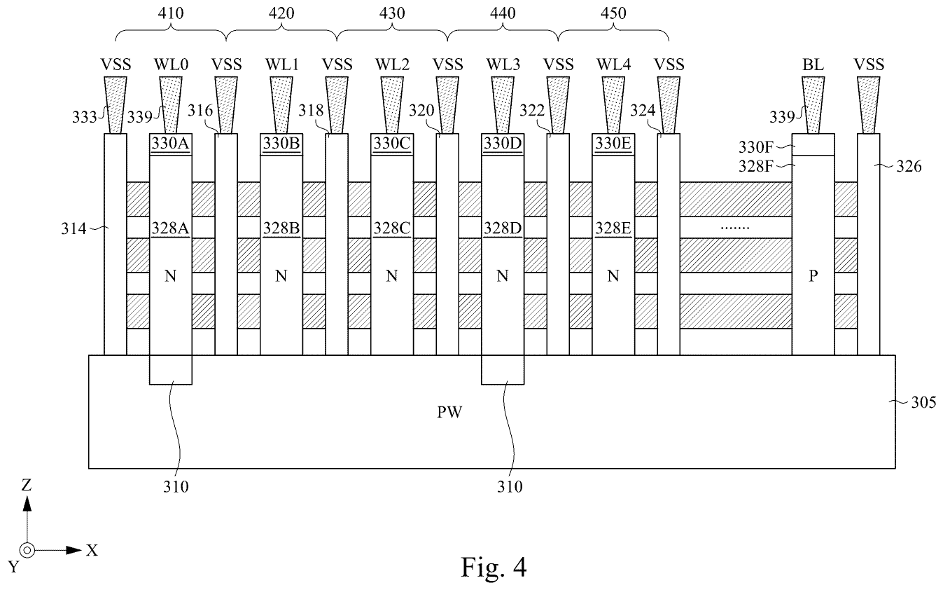

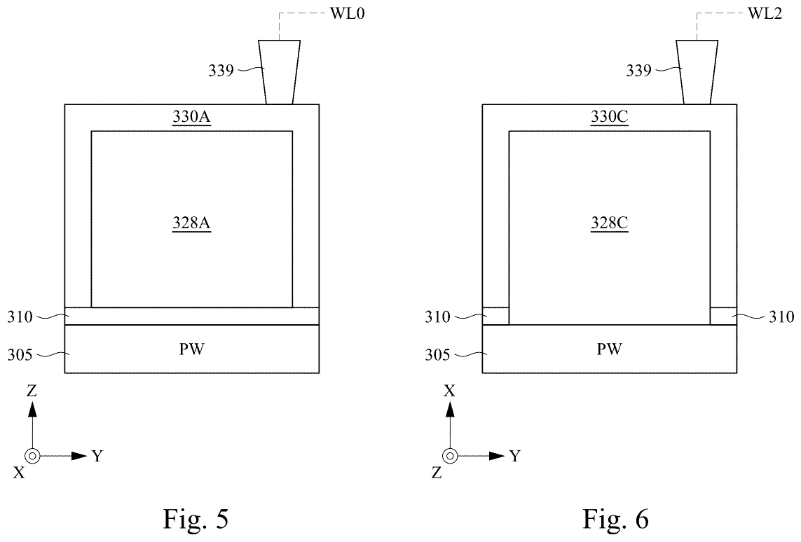

FIG. 3 illustrates an example layout 300 configured to form (or program) a memory array including a plural number of ROM cells (e.g., 5 ROM cells) that are arranged along the X-direction. In some embodiments, these ROM cells can be programmed with respective logic states based on processing techniques. FIG. 4, FIG. 5, and FIG. 6 illustrate cross-sectional views of the memory array formed based on the layout 300, respectively.

For example, FIG. 4 illustrates a hybrid cross-sectional view of the memory array cut along or parallel with line A-A′ (e.g., the X-direction), FIG. 5 illustrates a cross-sectional view of the memory array cut along line B-B′ (e.g., the Y-direction), and FIG. 6 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 3 and the corresponding cross-sectional views of FIGS. 4-6 are provided merely for illustrative purposes, and are not intended to limit the scope of the present disclosure.

Referring first to FIG. 3, the layout 300 includes patterns for forming a well 305, one or more dielectric layers 310 (better illustrated in the cross-sectional views of FIGS. 4-5), an active region 312, and gate structures 314, 316, 318, 320, 322, 324. 326, respectively. In some embodiments, the well 305 and the active region 312 can extend along a first lateral direction, e.g., the X-direction, while the gate structures 314 to 326 can each extend along a second lateral direction perpendicular to the first lateral direction, e.g., the Y-direction. As such, the gate structures 314 to 326 can each traverse the active region 312. The gate structures 314 to 326 can each correspond to an active (e.g., metal) gate structure. For example, the gate structure 314 to 326 can each formed as a polysilicon gate structure (sometimes referred to as a dummy gate structure), and then be replaced with a corresponding metal gate structure (sometimes referred to as an active gate structure). The well 305, the dielectric layer(s) 310, the active region 312, and the gate structures 314 to 326, which are formed along the major surface of a substrate, are sometimes referred to as part of front-end-of-line (FEOL) processing.

In the example of FIGS. 3-6, the ROM cells of the memory array are each formed as a diode, with its BL and WL being connected to or disconnected from each other, based on a gate-all-around (GAA) transistor structure. However, the ROM cells of the memory array (formed by the layout 300) can be formed as any of various other transistor structure while remaining within the scope of the present disclosure. With the GAA transistor structure, the active region 312 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 3-4, epitaxial structures 328A, 328B, 328C, 328D, 328E . . . 328F (formed in the active region 312) and the gate structures 314 to 326 can be alternately arranged along the X-direction. For example, along the X-direction, the epitaxial structure 328A is interposed between the gate structures 314 and 316, the epitaxial structure 328B is interposed between the gate structures 316 and 318, the epitaxial structure 328C is interposed between the gate structures 318 and 320, the epitaxial structure 328D is interposed between the gate structures 320 and 322, the epitaxial structure 328E is interposed between the gate structures 322 and 324, and the epitaxial structure 328F is interposed between a non-shown gate structure and the gate structure 326. Further, to program the ROM cells with different logic states, a first group of the epitaxial structures (e.g., 328A, 328D) can be physically separated (and/or electrically isolated) from the well 305 with the dielectric layers 310, respectively, and a second group of the epitaxial structures (e.g., 328B, 328C, 328E) can be in direct contact with the well 305.

According to some embodiments of the present disclosure, the well 305 is formed with a first conductive type (e.g., p-type), which is sometimes referred to as a p-well (PW) 305, while one of the epitaxial structures (e.g., 328F) is formed with the same first conductive type (p-type) and the rest of the epitaxial structures (e.g., 328A-E) are formed with a second, opposite conductive type (e.g., n-type). The epitaxial structure 328F can have a higher doping concentration than the PW 305. All the gate structures 314 to 326 can be electrically coupled to a supply voltage (e.g., VSS) such as, for example, to turn off the channels of the transistors. Similar to the ROM cell 100 (FIG. 1), the p-type epitaxial structure 328F, together with the PW 305, can operatively serve as a common positive terminal for the ROM cells, while each of the n-type epitaxial structures 328A-E can operatively serve as a negative terminal for the respective ROM cell. As will be discussed below, the common positive terminal of the ROM cells can be coupled to a common bit line BL, and the negative terminal of each of the ROM cells can be coupled to a respective word line WL. Further, the positive terminal and the negative terminal of each of the ROM cells can be electrically coupled to or isolated from each other, based on a desired logic state to be programmed to the ROM cell.

The layout 300 further includes patterns for forming source/drain contact structures (each sometimes referred to as an MD) 330A, 330B, 330C, 330D, 330E . . . 330F, respectively. Generally, each of the MDs 330A to 330F is disposed above a corresponding one of the epitaxial structures 328A to 328F, as shown in FIG. 4. The MDs 330A to 330F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 300 further includes patterns for forming a number of VDs 339 to electrically connect the underlying MD to an above interconnect structure. Similarly, the layout 300 further includes patterns for forming a number of other via structures 333 (each sometimes referred to as a VG) to electrically connect a corresponding underlying gate structure to an above interconnect structure. The layout 300 further includes patterns for forming those interconnect structures in the upper metallization layers, which will be discussed as follows. The MDs 339A-F, VGs 333, and VDs 339 are sometimes referred to as part of middle-end-of-line (MEOL) processing, and the interconnect structures in the metallization layers are sometimes referred to as part of back-end-of-line (BEOL) processing.

In the illustrative example of FIGS. 3-4, the gate structures 314 to 326 can be coupled to an interconnect structure 340 formed in a bottommost one of the metallization layers M0 (sometimes referred to as an M0 track 340) through respective VGs 333. In some embodiments, the M0 track 340 is configured to carry (or coupled to) the VSS, which electrically ties the gate structures 314 to 326 to the VSS. The MDs 328A to 328F can be coupled to other M0 tracks 344, 346, 348, 350, 352, and 354 through the respective VDs 339. The M0 tracks 344, 346, 348, 350, and 352 can be further coupled to respective interconnect structures, 360, 362, 364, 366, and 368, in a next bottommost one of the metallization layers M1 (sometimes referred to as M1 track 360, M1 track 362, M1 track 364, M1 track 366, and M1 track 368) through respective via structures. In some embodiments, the M1 track 360, M1 track 362, M1 track 364, M1 track 366, and M1 track 368 are configured as (or coupled to) word lines, WL0, WL1, WL2, WL3, and WL4, respectively, with the M0 track 354 configured as (or coupled to) a common bit line BL.

In some embodiments, ROM cells 410, 420, 430, 440, and 450 (FIG. 4) can be programmed, upon the above-described interconnect structures (e.g., the M0 tracks 340-354, the M1 tracks 360-368) being formed. For example, the ROM cell 410 is formed based on the epitaxial structure 328A, one of the dielectric layers 310, the PW 305, and the epitaxial structure 328F; the ROM cell 420 is formed based on the epitaxial structure 328B, the PW 305, and the epitaxial structure 328F; the ROM cell 430 is formed based on the epitaxial structure 328C, the PW 305, and the epitaxial structure 328F; the ROM cell 440 is formed based on the epitaxial structure 328D, another one of the dielectric layers 310, the PW 305, and the epitaxial structure 328F; and the ROM cell 450 is formed based on the epitaxial structure 328E, the PW 305, and the epitaxial structure 328F.

Specifically, the epitaxial structure 328A and the epitaxial structure 328F (together with the PW 305) can serve as the negative terminal and the positive terminal of the ROM cell 410; the epitaxial structure 328B and the epitaxial structure 328F (together with the PW 305) can serve as the negative terminal and the positive terminal of the ROM cell 420; the epitaxial structure 328C and the epitaxial structure 328F (together with the PW 305) can serve as the negative terminal and the positive terminal of the ROM cell 430; the epitaxial structure 328D and the epitaxial structure 328F (together with the PW 305) can serve as the negative terminal and the positive terminal of the ROM cell 440; and the epitaxial structure 328E and the epitaxial structure 328F (together with the PW 305) can serve as the negative terminal and the positive terminal of the ROM cell 450.

With the dielectric layer 310 interposed between the epitaxial structure 328A and the PW 305, the ROM cell 410 can be formed as a disconnected diode. For example, the epitaxial structure 328A and the PW 305 are electrically isolated from each other with the dielectric layer 310. Similarly, the ROM cell 440 can be formed as a disconnected diode, given the dielectric layer 310 interposed between the epitaxial structure 328D and the PW 305. Although in the cross-sectional view of FIG. 4, the dielectric layer 310 is illustrated as having its sidewall aligned with the corresponding epitaxial structure (e.g., 328A, 328D), it should be appreciated that the dielectric layer 310 can extend farther than the corresponding epitaxial structure (in the X-direction). On the other hand, each of the epitaxial structures 328B, 328C, and 328E is in direct contact with the PW 305, thereby forming the ROM cells 420, 430, and 450 as connected diodes, respectively. In some embodiments, the disconnected diode may be associated with logic 0, and the connected diode may be associated with logic 1. Consequently, upon being formed, the ROM cells 410, 420, 430, 440, and 450 can be programmed with logic 0, logic 1, logic 1, logic 0, and logic 1, respectively.

Referring next to FIGS. 5 and 6, the cross-sectional view cut along line B-B′ (or epitaxial structure 328A in FIG. 3) and the cross-sectional view cut along line C-C′ (or epitaxial structure 328C in FIG. 3) are shown, respectively. In FIG. 5, the epitaxial structure 328A is physically separated from the PW 305, which causes the epitaxial structure 328A to be electrically isolated from the PW 305. Further, in some embodiments, the epitaxial structure 328A is electrically coupled to the word line WL0 through the MD 330A and corresponding VD 339, while the PW 305 is electrically coupled to the common bit line BL through the epitaxial structure 328F, MD 330F, and corresponding VD 339 (FIG. 4). In some embodiments, the MD 330A may be electrically isolated from the PW 305 with the dielectric layer 310. In FIG. 6, with the PW 305 electrically coupled to the common bit line BL through the epitaxial structure 328F, MD 330F, and corresponding VD 339 (FIG. 4), the epitaxial structure 328C is electrically coupled to the word line WL2 through the MD 330C and corresponding VD 339. Further, the epitaxial structure 328C can be in direct contact with the PW 305. In some embodiments, the MD 330C may be electrically isolated from the PW 305 with yet another dielectric layer 310.

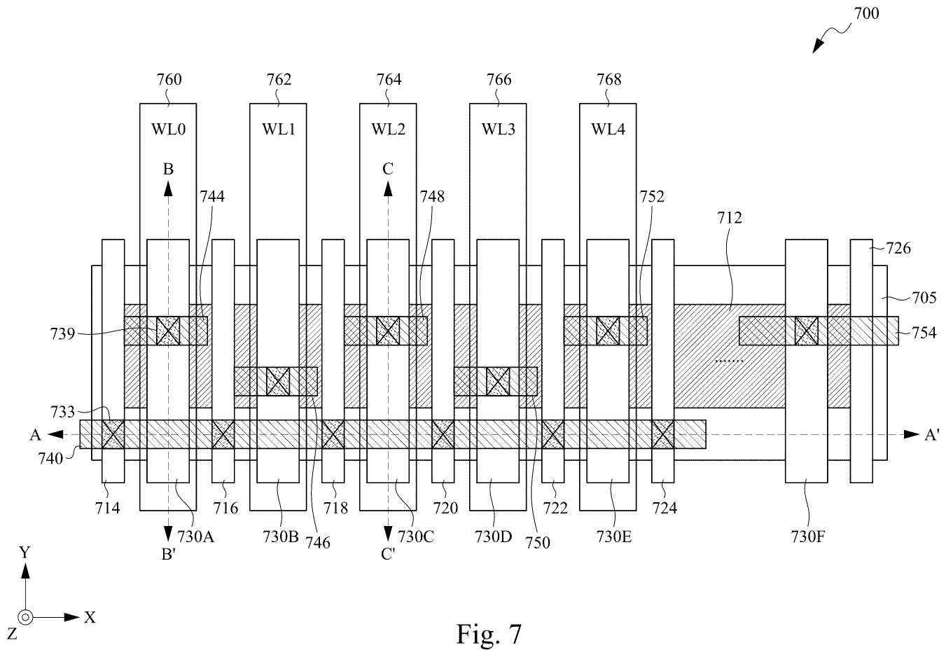

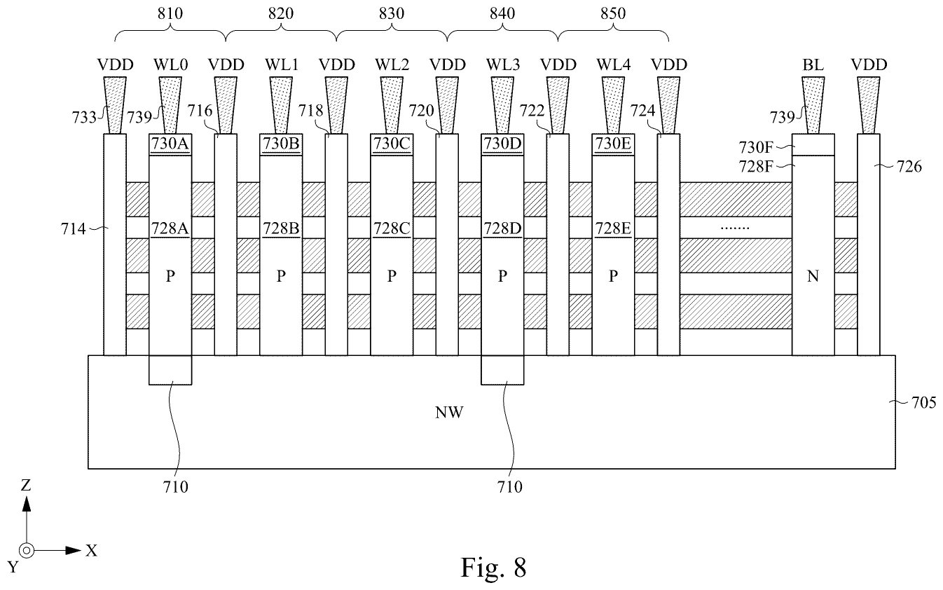

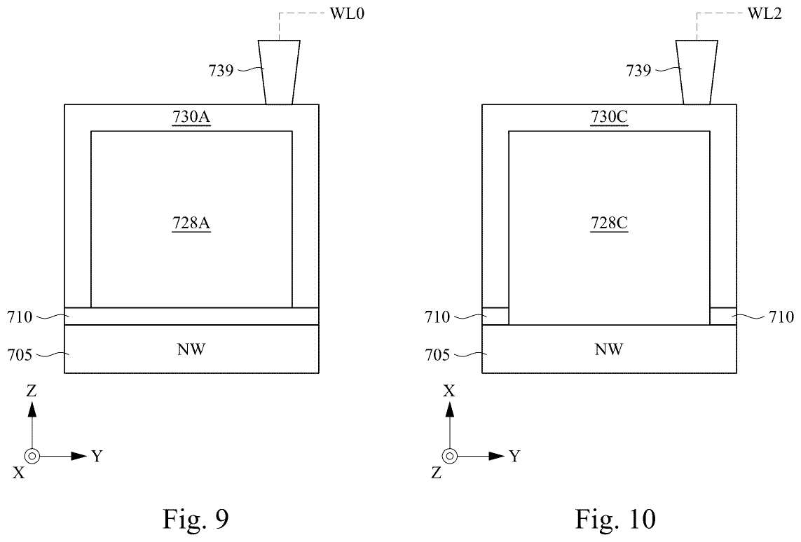

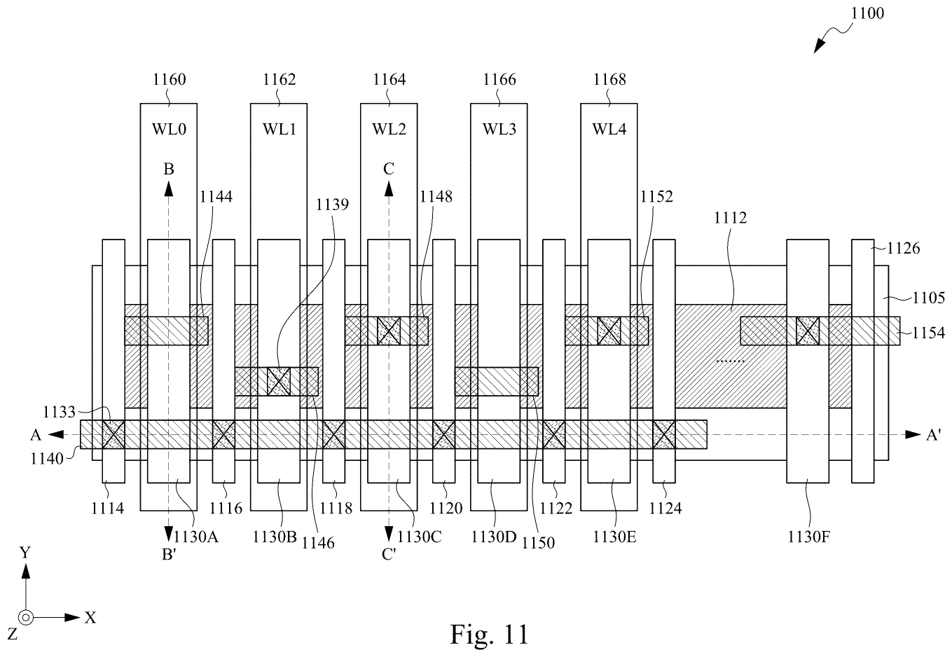

FIG. 7 illustrates an example layout 700 configured to form (or program) a memory array including a plural number of ROM cells (e.g., 5 ROM cells) that are arranged along the X-direction. In some embodiments, these ROM cells can be programmed with respective logic states based on processing techniques. FIG. 8, FIG. 9, and FIG. 10 illustrate cross-sectional views of the memory array formed based on the layout 700, respectively.

For example, FIG. 8 illustrates a hybrid cross-sectional view of the memory array cut along or parallel with line A-A′ (e.g., the X-direction), FIG. 9 illustrates a cross-sectional view of the memory array cut along line B-B′ (e.g., the Y-direction), and FIG. 10 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 7 and the corresponding cross-sectional views of FIGS. 8-10 are provided merely for illustrative purposes, and are not intended to limit the scope of the present disclosure.

Referring first to FIG. 7, the layout 700 includes patterns for forming a well 705, one or more dielectric layers 710 (better illustrated in the cross-sectional views of FIGS. 8-9), an active region 712, and gate structures 714, 716, 718, 720, 722, 724. 726, respectively. In some embodiments, the well 705 and the active region 712 can extend along a first lateral direction, e.g., the X-direction, while the gate structures 714 to 726 can each extend along a second lateral direction perpendicular to the first lateral direction, e.g., the Y-direction. As such, the gate structures 714 to 726 can each traverse the active region 712. The gate structures 714 to 726 can each correspond to an active (e.g., metal) gate structure. For example, the gate structure 714 to 726 can each formed as a polysilicon gate structure (sometimes referred to as a dummy gate structure), and then be replaced with a corresponding metal gate structure (sometimes referred to as an active gate structure). The well 705, the dielectric layer(s) 710, the active region 712, and the gate structures 714 to 726, which are formed along the major surface of a substrate, are sometimes referred to as part of front-end-of-line (FEOL) processing.

In the example of FIGS. 7-10, the ROM cells of the memory array are each formed as a diode, with its BL and WL being connected to or disconnected from each other, based on a gate-all-around (GAA) transistor structure. However, the ROM cells of the memory array (formed by the layout 700) can be formed as any of various other transistor structure while remaining within the scope of the present disclosure. With the GAA transistor structure, the active region 712 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 7-8, epitaxial structures 728A, 728B, 728C, 728D, 728E . . . 728F (formed in the active region 712) and the gate structures 714 to 726 can be alternately arranged along the X-direction. For example, along the X-direction, the epitaxial structure 728A is interposed between the gate structures 714 and 716, the epitaxial structure 728B is interposed between the gate structures 716 and 718, the epitaxial structure 728C is interposed between the gate structures 718 and 720, the epitaxial structure 728D is interposed between the gate structures 720 and 722, the epitaxial structure 728E is interposed between the gate structures 722 and 724, and the epitaxial structure 728F is interposed between a non-shown gate structure and the gate structure 726. Further, to program the ROM cells with different logic states, a first group of the epitaxial structures (e.g., 728A, 728D) can be physically separated (and/or electrically isolated) from the well 705 with the dielectric layers 710, respectively, and a second group of the epitaxial structures (e.g., 728B, 728C, 728E) can be in direct contact with the well 705.

According to some embodiments of the present disclosure, the well 705 is formed with a first conductive type (e.g., n-type), which is sometimes referred to as an n-well (NW) 705, while one of the epitaxial structures (e.g., 728F) is formed with the same first conductive type (n-type) and the rest of the epitaxial structures (e.g., 728A-E) are formed with a second, opposite conductive type (e.g., p-type). The epitaxial structure 728F can have a higher doping concentration than the NW 705. All the gate structures 714 to 726 can be electrically coupled to a supply voltage (e.g., VDD) such as, for example, to turn off the channels of the transistors. Similar to the ROM cell 200 (FIG. 2), the n-type epitaxial structure 728F, together with the NW 705, can operatively serve as a common negative terminal for the ROM cells, while each of the p-type epitaxial structures 728A-E can operatively serve as a positive terminal for the respective ROM cell. As will be discussed below, the common negative terminal of the ROM cells can be coupled to a common bit line BL, and the positive terminal of each of the ROM cells can be coupled to a respective word line WL. Further, the positive terminal and the negative terminal of each of the ROM cells can be electrically coupled to or isolated from each other, based on a desired logic state to be programmed to the ROM cell.

The layout 700 further includes patterns for forming source/drain contact structures (each sometimes referred to as an MD) 730A, 730B, 730C, 730D, 730E . . . 730F, respectively. Generally, each of the MDs 730A to 730F is disposed above a corresponding one of the epitaxial structures 728A to 728F, as shown in FIG. 8. The MDs 730A to 730F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 700 further includes patterns for forming a number of VDs 739 to electrically connect the underlying MD to an above interconnect structure. Similarly, the layout 700 further includes patterns for forming a number of other via structures 733 (each sometimes referred to as a VG) to electrically connect a corresponding underlying gate structure to an above interconnect structure. The layout 700 further includes patterns for forming those interconnect structures in the upper metallization layers, which will be discussed as follows. The MDs 739A-F, VGs 733, and VDs 739 are sometimes referred to as part of middle-end-of-line (MEOL) processing, and the interconnect structures in the metallization layers are sometimes referred to as part of back-end-of-line (BEOL) processing.

In the illustrative example of FIGS. 7-8, the gate structures 714 to 726 can be coupled to an interconnect structure 740 formed in a bottommost one of the metallization layers M0 (sometimes referred to as an M0 track 740) through respective VGs 733. In some embodiments, the M0 track 740 is configured to carry (or coupled to) the VDD, which electrically ties the gate structures 714 to 726 to the VDD. The MDs 728A to 728F can be coupled to other M0 tracks 744, 746, 748, 750, 752, and 754 through the respective VDs 739. The M0 tracks 744, 746, 748, 750, and 752 can be further coupled to respective interconnect structures, 760, 762, 764, 766, and 768, in a next bottommost one of the metallization layers M1 (sometimes referred to as M1 track 760, M1 track 762, M1 track 764, M1 track 766, and M1 track 768) through respective via structures. In some embodiments, the M1 track 760, M1 track 762, M1 track 764, M1 track 766, and M1 track 768 are configured as (or coupled to) word lines, WL0, WL1, WL2, WL3, and WL4, respectively, with the M0 track 754 configured as (or coupled to) a common bit line BL.

In some embodiments, ROM cells 810, 820, 830, 840, and 850 (FIG. 8) can be programmed, upon the above-described interconnect structures (e.g., the M0 tracks 740-754, the M1 tracks 760-768) being formed. For example, the ROM cell 810 is formed based on the epitaxial structure 728A, one of the dielectric layers 710, the NW 705, and the epitaxial structure 728F; the ROM cell 820 is formed based on the epitaxial structure 728B, the NW 705, and the epitaxial structure 728F; the ROM cell 830 is formed based on the epitaxial structure 728C, the NW 705, and the epitaxial structure 728F; the ROM cell 840 is formed based on the epitaxial structure 728D, another one of the dielectric layers 710, the NW 705, and the epitaxial structure 728F; and the ROM cell 850 is formed based on the epitaxial structure 728E, the NW 705, and the epitaxial structure 728F.

Specifically, the epitaxial structure 728A and the epitaxial structure 728F (together with the NW 705) can serve as the positive terminal and the negative terminal of the ROM cell 810; the epitaxial structure 728B and the epitaxial structure 728F (together with the NW 705) can serve as the positive terminal and the negative terminal of the ROM cell 820; the epitaxial structure 728C and the epitaxial structure 728F (together with the NW 7305) can serve as the positive terminal and the negative terminal of the ROM cell 830; the epitaxial structure 728D and the epitaxial structure 728F (together with the NW 705) can serve as the positive terminal and the negative terminal of the ROM cell 840; and the epitaxial structure 728E and the epitaxial structure 728F (together with the NW 705) can serve as the positive terminal and the negative of the ROM cell 850.

With the dielectric layer 710 interposed between the epitaxial structure 728A and the NW 705, the ROM cell 810 can be formed as a disconnected diode. For example, the epitaxial structure 728A and the NW 705 are electrically isolated from each other with the dielectric layer 710. Similarly, the ROM cell 840 can be formed as a disconnected diode, given the dielectric layer 710 interposed between the epitaxial structure 728D and the NW 705. Although in the cross-sectional view of FIG. 8, the dielectric layer 710 is illustrated as having its sidewall aligned with the corresponding epitaxial structure (e.g., 728A, 728D), it should be appreciated that the dielectric layer 710 can extend farther than the corresponding epitaxial structure (in the X-direction). On the other hand, each of the epitaxial structures 728B, 728C, and 728E is in direct contact with the NW 705, thereby forming the ROM cells 820, 830, and 850 as connected diodes, respectively. In some embodiments, the disconnected diode may be associated with logic 0, and the connected diode may be associated with logic 1. Consequently, the ROM cells 810, 820, 830, 840, and 80 can be programmed with logic 0, logic 1, logic 1, logic 0, and logic 1, respectively.

Referring next to FIGS. 9 and 10, the cross-sectional view cut along line B-B′ (or epitaxial structure 728A in FIG. 7) and the cross-sectional view cut along line C-C′ (or epitaxial structure 728C in FIG. 7) are shown, respectively. In FIG. 9, the epitaxial structure 728A is physically separated from the NW 705, which causes the epitaxial structure 728A to be electrically isolated from the NW 705. Further, in some embodiments, the epitaxial structure 728A is electrically coupled to the word line WL0 through the MD 730A and corresponding VD 739, while the NW 705 is electrically coupled to the common bit line BL through the epitaxial structure 728F, MD 730F, and corresponding VD 739 (FIG. 8). In some embodiments, the MD 730A may be electrically isolated from the NW 705 with the dielectric layer 710. In FIG. 10, with the NW 705 electrically coupled to the common bit line BL through the epitaxial structure 728F, MD 730F, and corresponding VD 739 (FIG. 8), the epitaxial structure 728C is electrically coupled to the word line WL2 through the MD 730C and corresponding VD 739. Further, the epitaxial structure 728C can be in direct contact with the NW 705. In some embodiments, the MD 730C may be electrically isolated from the NW 705 with yet another dielectric layer 710.

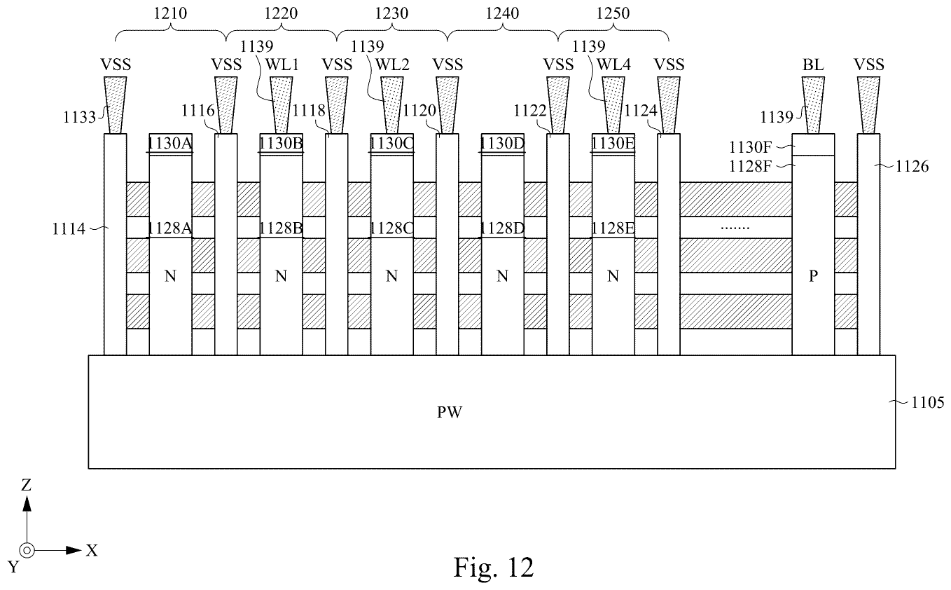

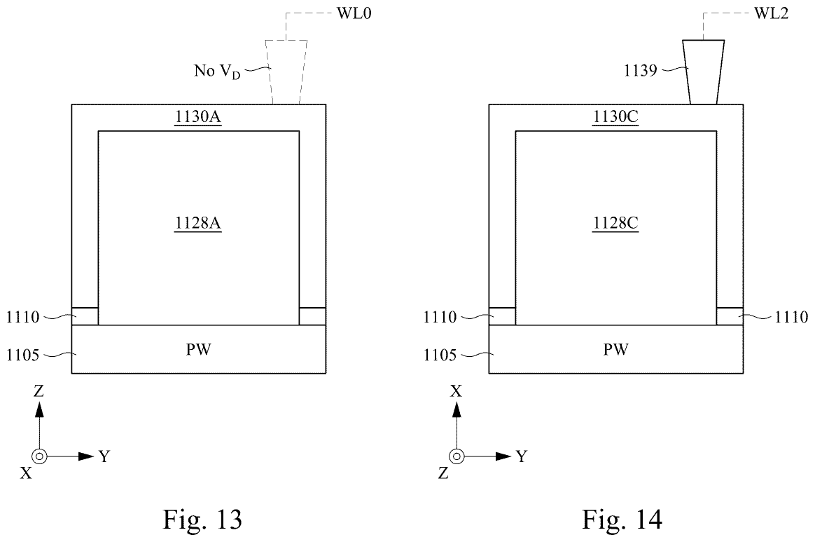

FIG. 11 illustrates an example layout 1100 configured to form (or program) a memory array including a plural number of ROM cells (e.g., 5 ROM cells) that are arranged along the X-direction. In some embodiments, these ROM cells can be programmed with respective logic states based on processing techniques. FIG. 12, FIG. 13, and FIG. 14 illustrate cross-sectional views of the memory array formed based on the layout 1100, respectively.

For example, FIG. 12 illustrates a hybrid cross-sectional view of the memory array cut along or parallel with line A-A′ (e.g., the X-direction), FIG. 13 illustrates a cross-sectional view of the memory array cut along line B-B′ (e.g., the Y-direction), and FIG. 14 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 11 and the corresponding cross-sectional views of FIGS. 12-14 are provided merely for illustrative purposes, and are not intended to limit the scope of the present disclosure.

Referring first to FIG. 11, the layout 1100 includes patterns for forming a well 1105, one or more dielectric layers 1110 (better illustrated in the cross-sectional views of FIGS. 13-14), an active region 1112, and gate structures 1114, 1116, 1118, 1120, 1122, 1124 . . . 1126, respectively. In some embodiments, the well 1105 and the active region 1112 can extend along a first lateral direction, e.g., the X-direction, while the gate structures 1114 to 1126 can each extend along a second lateral direction perpendicular to the first lateral direction, e.g., the Y-direction. As such, the gate structures 1114 to 1126 can each traverse the active region 1112. The gate structures 1114 to 1126 can each correspond to an active (e.g., metal) gate structure. For example, the gate structure 1114 to 1126 can each formed as a polysilicon gate structure (sometimes referred to as a dummy gate structure), and then be replaced with a corresponding metal gate structure (sometimes referred to as an active gate structure). The well 1105, the dielectric layer(s) 1110, the active region 1112, and the gate structures 1114 to 1126, which are formed along the major surface of a substrate, are sometimes referred to as part of front-end-of-line (FEOL) processing.

In the example of FIGS. 11-14, the ROM cells of the memory array are each formed as a diode, with its BL and WL being connected to or disconnected from each other, based on a gate-all-around (GAA) transistor structure. However, the ROM cells of the memory array (formed by the layout 1100) can be formed as any of various other transistor structure while remaining within the scope of the present disclosure. With the GAA transistor structure, the active region 1112 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 11-12, epitaxial structures 1128A, 1128B, 1128C, 1128D, 1128E . . . 1128F (formed in the active region 1112) and the gate structures 1114 to 1126 can be alternately arranged along the X-direction. For example, along the X-direction, the epitaxial structure 1128A is interposed between the gate structures 1114 and 1116, the epitaxial structure 1128B is interposed between the gate structures 1116 and 1118, the epitaxial structure 1128C is interposed between the gate structures 1118 and 1120, the epitaxial structure 1128D is interposed between the gate structures 1120 and 1122, the epitaxial structure 1128E is interposed between the gate structures 1122 and 1124, and the epitaxial structure 1128F is interposed between a non-shown gate structure and the gate structure 1126. Further, to program the ROM cells with different logic states, a first group of the epitaxial structures (e.g., 1128A, 1128D) can be electrically isolated from upper interconnect structures functioning as respective word lines WLs, and a second group of the epitaxial structures (e.g., 1128B, 1128C, 1128E) can be electrically coupled to upper interconnect structures functioning as respective word lines WLs. In some embodiments, all the epitaxial structures 1128A to 1128F may be in contact with the well 1105.

According to some embodiments of the present disclosure, the well 1105 is formed with a first conductive type (e.g., p-type), which is sometimes referred to as a p-well (PW) 1105, while one of the epitaxial structures (e.g., 1128F) is formed with the same first conductive type (p-type) and the rest of the epitaxial structures (e.g., 1128A-E) are formed with a second, opposite conductive type (e.g., n-type). The epitaxial structure 1128F can have a higher doping concentration than the PW 1105. All the gate structures 1114 to 1126 can be electrically coupled to a supply voltage (e.g., VSS) such as, for example, to turn off the channels of the transistors. Similar to the ROM cell 100 (FIG. 1), the p-type epitaxial structure 1128F, together with the PW 1105, can operatively serve as a common positive terminal for the ROM cells, while each of the n-type epitaxial structures 1128A-E can operatively serve as a negative terminal for the respective ROM cell. As will be discussed below, the common positive terminal of the ROM cells can be coupled to a common bit line BL, and the negative terminal of each of the ROM cells can be selectively coupled to a respective word line WL. Further, the negative terminal of each of the ROM cells can be electrically coupled to or isolated from the respective word line WL, based on a desired logic state to be programmed to the ROM cell.

The layout 1100 further includes patterns for forming source/drain contact structures (each sometimes referred to as an MD) 1130A, 1130B, 1130C, 1130D, 1130E . . . 1130F, respectively. Generally, each of the MDs 1130A to 1130F is disposed above a corresponding one of the epitaxial structures 1128A to 1128F, as shown in FIG. 12. The MDs 1130A to 1130F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 1100 further includes patterns for forming a number of VDs 1139 to electrically connect the underlying MD to an above interconnect structure. In the example of FIGS. 11-14, the epitaxial structures 1128B, 1128C, 1128E, and 1128F are connected to the respective VDs 1139, while the epitaxial structures 1128A and 1128D are not connected to a VD 1139.

The layout 1100 further includes patterns for forming a number of other via structures 1133 (each sometimes referred to as a VG) to electrically connect a corresponding underlying gate structure to an above interconnect structure. The layout 1100 further includes patterns for forming those interconnect structures in the upper metallization layers, which will be discussed as follows. The MDs 1139A-F, VGs 1133, and VDs 1139 are sometimes referred to as part of middle-end-of-line (MEOL) processing, and the interconnect structures in the metallization layers are sometimes referred to as part of back-end-of-line (BEOL) processing.

In the illustrative example of FIGS. 11-12, the gate structures 1114 to 1126 can be coupled to an interconnect structure 1140 formed in a bottommost one of the metallization layers M0 (sometimes referred to as an M0 track 1140) through respective VGs 1133. In some embodiments, the M0 track 1140 is configured to carry (or coupled to) the VSS, which electrically ties the gate structures 1114 to 1126 to the VSS. The MDs 1128A to 1128F can be coupled to other M0 tracks 1144, 1146, 1148, 1150, 1152, and 1154 through the respective VDs 1139. The M0 tracks 1144, 1146, 1148, 1150, and 1152 can be further coupled to respective interconnect structures, 1160, 1162, 1164, 1166, and 1168, in a next bottommost one of the metallization layers M1 (sometimes referred to as M1 track 1160, M1 track 1162, M1 track 1164, M1 track 1166, and M1 track 1168) through respective via structures. In some embodiments, the M1 track 1160, M1 track 1162, M1 track 1164, M1 track 1166, and M1 track 1168 are configured as (or coupled to) word lines, WL0, WL1, WL2, WL3, and WL4, respectively, with the M0 track 1154 configured as (or coupled to) a common bit line BL.

In some embodiments, ROM cells 1210, 1220, 1230, 1240, and 1250 (FIG. 12) can be programmed, upon the above-described interconnect structures (e.g., the M0 tracks 1140-1154, the M1 tracks 1160-1168) being formed. For example, the ROM cell 1210 is formed based on the epitaxial structure 1128A, the PW 1105, and the epitaxial structure 1128F; the ROM cell 1120 is formed based on the epitaxial structure 1128B, the PW 1105, and the epitaxial structure 1128F; the ROM cell 1230 is formed based on the epitaxial structure 1128C, the PW 1105, and the epitaxial structure 1128F; the ROM cell 1240 is formed based on the epitaxial structure 1128D, the PW 1105, and the epitaxial structure 1128F; and the ROM cell 1250 is formed based on the epitaxial structure 1128E, the PW 1105, and the epitaxial structure 1128F.

Specifically, the epitaxial structure 1128A and the epitaxial structure 1128F (together with the PW 1105) can serve as the negative terminal and the positive terminal of the ROM cell 1210; the epitaxial structure 1128B and the epitaxial structure 1128F (together with the PW 1105) can serve as the negative terminal and the positive terminal of the ROM cell 1220; the epitaxial structure 1128C and the epitaxial structure 1128F (together with the PW 1105) can serve as the negative terminal and the positive terminal of the ROM cell 1230; the epitaxial structure 1128D and the epitaxial structure 1128F (together with the PW 1105) can serve as the negative terminal and the positive terminal of the ROM cell 1240; and the epitaxial structure 1128E and the epitaxial structure 1128F (together with the PW 1105) can serve as the negative terminal and the positive terminal of the ROM cell 1250.

With no VD formed between the M0 track 1144 (connected to the word line WL0) and the MD 1130A, the ROM cell 1210 can be formed as a disconnected diode. For example, the MD 1130A is electrically isolated from the M0 track 1144 or the word line WL0 through no VD being formed. Similarly, the ROM cell 1240 can be formed as a disconnected diode, given that no VD formed between the MD 1130D and the M0 track 1150 (connected to the word line WL3). On the other hand, the epitaxial structures 1128B, 1128C, and 1128E are coupled to the word lines WL1 (through M0 track 1146 and VD 1139), WL2 (through M0 track 1148 and VD 1139), and WLA (through M0 track 1152 and VD 1139), respectively, thereby forming the ROM cells 1220, 1230, and 1250 as connected diodes, respectively. In some embodiments, the disconnected diode may be associated with logic 0, and the connected diode may be associated with logic 1. Consequently, upon being formed, the ROM cells 1210, 1220, 1230, 1240, and 1250 can be programmed with logic 0, logic 1, logic 1, logic 0, and logic 1, respectively.

Referring next to FIGS. 13 and 14, the cross-sectional view cut along line B-B′ (or epitaxial structure 1128A in FIG. 11) and the cross-sectional view cut along line C-C′ (or epitaxial structure 1128C in FIG. 11) are shown, respectively. In FIG. 13, with the PW 1105 electrically coupled to the common bit line BL through the epitaxial structure 1128F, MD 1130F, and corresponding VD 1139 (FIG. 12), the epitaxial structure 1128A is electrically decoupled from the word line WL0 through no VD being formed. Further, the epitaxial structure 1128A can be in direct contact with the PW 1105. In some embodiments, the MD 1130A may be electrically isolated from the PW 1105 with the dielectric layer 1110. In FIG. 14, with the PW 1105 electrically coupled to the common bit line BL through the epitaxial structure 1128F, MD 1130F, and corresponding VD 1139 (FIG. 12), the epitaxial structure 1128C is electrically coupled to the word line WL2 through the MD 1130C and corresponding VD 1139. Further, the epitaxial structure 1128C can be in direct contact with the PW 1105. In some embodiments, the MD 1130C may be electrically isolated from the PW 1105 with another dielectric layer 1110.

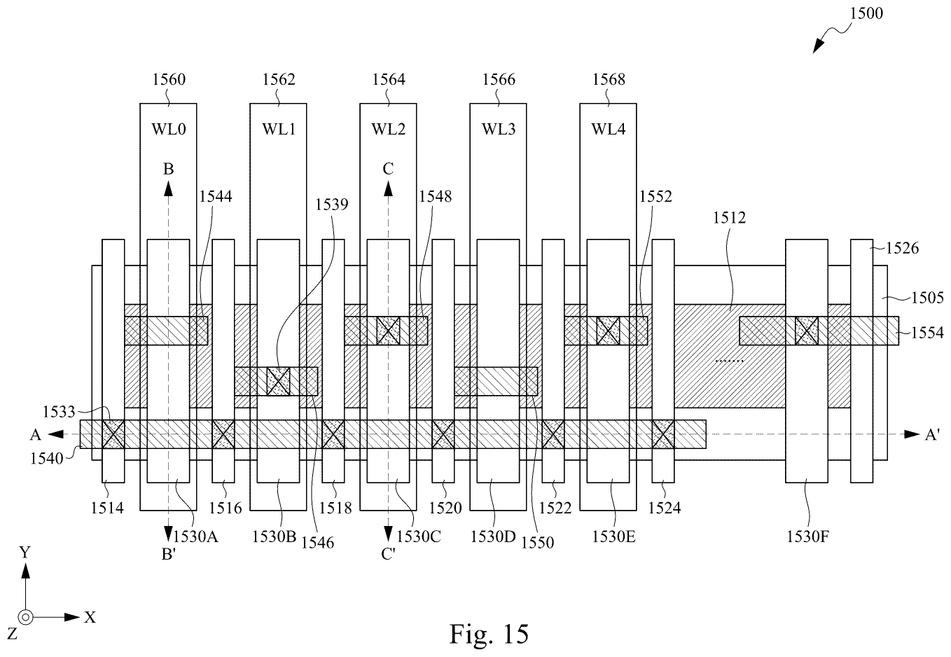

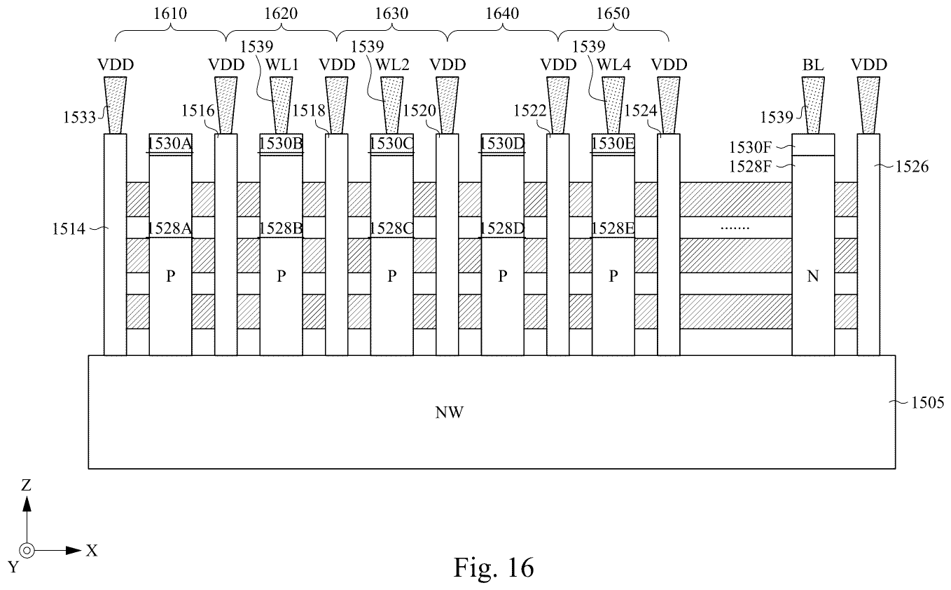

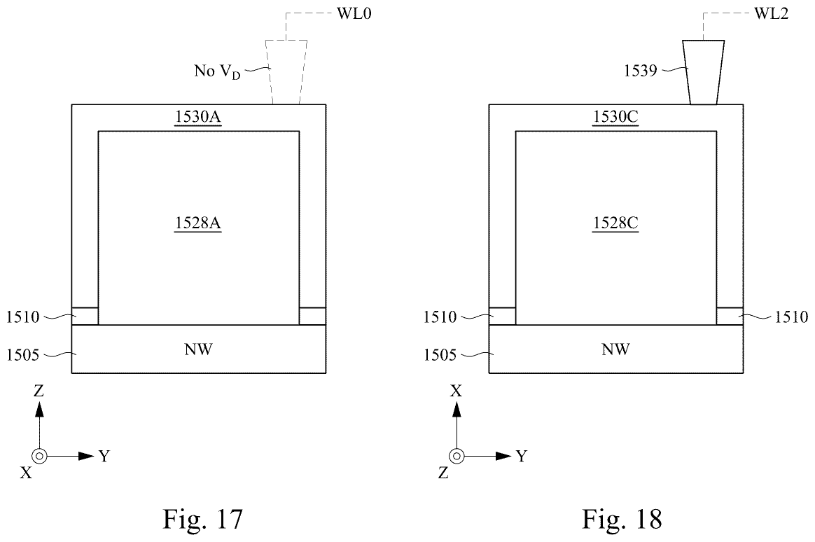

FIG. 15 illustrates an example layout 1500 configured to form (or program) a memory array including a plural number of ROM cells (e.g., 5 ROM cells) that are arranged along the X-direction. In some embodiments, these ROM cells can be programmed with respective logic states based on processing techniques. FIG. 16, FIG. 17, and FIG. 18 illustrate cross-sectional views of the memory array formed based on the layout 1500, respectively.

For example, FIG. 16 illustrates a hybrid cross-sectional view of the memory array cut along or parallel with line A-A′ (e.g., the X-direction), FIG. 17 illustrates a cross-sectional view of the memory array cut along line B-B′ (e.g., the Y-direction), and FIG. 18 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 15 and the corresponding cross-sectional views of FIGS. 16-18 are provided merely for illustrative purposes, and are not intended to limit the scope of the present disclosure.

Referring first to FIG. 15, the layout 1500 includes patterns for forming a well 1505, one or more dielectric layers 1510 (better illustrated in the cross-sectional views of FIGS. 16-18), an active region 1512, and gate structures 1514, 1516, 1518, 1520, 1522, 1524 . . . 1526, respectively. In some embodiments, the well 1505 and the active region 1512 can extend along a first lateral direction, e.g., the X-direction, while the gate structures 1514 to 1526 can each extend along a second lateral direction perpendicular to the first lateral direction, e.g., the Y-direction. As such, the gate structures 1514 to 1526 can each traverse the active region 1512. The gate structures 1514 to 1526 can each correspond to an active (e.g., metal) gate structure. For example, the gate structure 1514 to 1526 can each formed as a polysilicon gate structure (sometimes referred to as a dummy gate structure), and then be replaced with a corresponding metal gate structure (sometimes referred to as an active gate structure). The well 1505, the dielectric layer(s) 1510, the active region 1512, and the gate structures 1514 to 1526, which are formed along the major surface of a substrate, are sometimes referred to as part of front-end-of-line (FEOL) processing.

In the example of FIGS. 15-18, the ROM cells of the memory array are each formed as a diode, with its BL and WL being connected to or disconnected from each other, based on a gate-all-around (GAA) transistor structure. However, the ROM cells of the memory array (formed by the layout 1500) can be formed as any of various other transistor structure while remaining within the scope of the present disclosure. With the GAA transistor structure, the active region 1512 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 15-16, epitaxial structures 1528A, 1528B, 1528C, 1528D, 1528E . . . 1528F (formed in the active region 1512) and the gate structures 1514 to 1526 can be alternately arranged along the X-direction. For example, along the X-direction, the epitaxial structure 1528A is interposed between the gate structures 1514 and 1516, the epitaxial structure 1528B is interposed between the gate structures 1516 and 1518, the epitaxial structure 1528C is interposed between the gate structures 1518 and 1520, the epitaxial structure 1528D is interposed between the gate structures 1520 and 1522, the epitaxial structure 1528E is interposed between the gate structures 1522 and 1524, and the epitaxial structure 1528F is interposed between a non-shown gate structure and the gate structure 1526. Further, to program the ROM cells with different logic states, a first group of the epitaxial structures (e.g., 1528A, 1528D) can be electrically isolated from upper interconnect structures functioning as respective word lines WLs, and a second group of the epitaxial structures (e.g., 1528B, 1528C, 1528E) can be electrically coupled to upper interconnect structures functioning as respective word lines WLs. In some embodiments, all the epitaxial structures 1528A to 1528F may be in contact with the well 1505.

According to some embodiments of the present disclosure, the well 1505 is formed with a first conductive type (e.g., n-type), which is sometimes referred to as an n-well (NW) 1505, while one of the epitaxial structures (e.g., 1528F) is formed with the same first conductive type (n-type) and the rest of the epitaxial structures (e.g., 1528A-E) are formed with a second, opposite conductive type (e.g., p-type). The epitaxial structure 1528F can have a higher doping concentration than the NW 1505. All the gate structures 1514 to 1526 can be electrically coupled to a supply voltage (e.g., VDD) such as, for example, to turn off the channels of the transistors. Similar to the ROM cell 200 (FIG. 2), the n-type epitaxial structure 1528F, together with the NW 1505, can operatively serve as a common negative terminal for the ROM cells, while each of the p-type epitaxial structures 1528A-E can operatively serve as a positive terminal for the respective ROM cell. As will be discussed below, the common negative terminal of the ROM cells can be coupled to a common bit line BL, and the positive terminal of each of the ROM cells can be selectively coupled to a respective word line WL. Further, the positive terminal of each of the ROM cells can be electrically coupled to or isolated from the respective word line WL, based on a desired logic state to be programmed to the ROM cell.

The layout 1500 further includes patterns for forming source/drain contact structures (each sometimes referred to as an MD) 1530A, 1530B, 1530C, 1530D, 1530E . . . 1530F, respectively. Generally, each of the MDs 1530A to 1530F is disposed above a corresponding one of the epitaxial structures 1528A to 1528F, as shown in FIG. 16. The MDs 1530A to 1530F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 1500 further includes patterns for forming a number of VDs 1539 to electrically connect the underlying MD to an above interconnect structure. In the example of FIGS. 15-18, the epitaxial structures 1528B, 1528C, 1528E, and 1528F are connected to the respective VDs 1539, while the epitaxial structures 1528A and 1528D are not connected to a VD 1539.

The layout 1500 further includes patterns for forming a number of other via structures 1533 (each sometimes referred to as a VG) to electrically connect a corresponding underlying gate structure to an above interconnect structure. The layout 1500 further includes patterns for forming those interconnect structures in the upper metallization layers, which will be discussed as follows. The MDs 1539A-F, VGs 1533, and VDs 1539 are sometimes referred to as part of middle-end-of-line (MEOL) processing, and the interconnect structures in the metallization layers are sometimes referred to as part of back-end-of-line (BEOL) processing.

In the illustrative example of FIGS. 15-16, the gate structures 1514 to 1526 can be coupled to an interconnect structure 1540 formed in a bottommost one of the metallization layers M0 (sometimes referred to as an M0 track 1540) through respective VGs 1533. In some embodiments, the M0 track 1540 is configured to carry (or coupled to) the VDD, which electrically ties the gate structures 1514 to 1526 to the VDD. The MDs 1528A to 1528F can be coupled to other M0 tracks 1544, 1546, 1548, 1550, 1552, and 1554 through the respective VDs 1539. The M0 tracks 1544, 1546, 1548, 1550, and 1552 can be further coupled to respective interconnect structures, 1560, 1562, 1564, 1566, and 1568, in a next bottommost one of the metallization layers M1 (sometimes referred to as M1 track 1560, M1 track 1562, M1 track 1564, M1 track 1566, and M1 track 1568) through respective via structures. In some embodiments, the M1 track 1560, M1 track 1562, M1 track 1564, M1 track 1566, and M1 track 1568 are configured as (or coupled to) word lines, WL0, WL1, WL2, WL3, and WL4, respectively, with the M0 track 1554 configured as (or coupled to) a common bit line BL.

In some embodiments, ROM cells 1610, 1620, 1630, 1640, and 1650 (FIG. 16) can be programmed, upon the above-described interconnect structures (e.g., the M0 tracks 1540-1554, the M1 tracks 1560-1568) being formed. For example, the ROM cell 1610 is formed based on the epitaxial structure 1528A, the NW 1505, and the epitaxial structure 1528F; the ROM cell 1620 is formed based on the epitaxial structure 1528B, the NW 1505, and the epitaxial structure 1528F; the ROM cell 1630 is formed based on the epitaxial structure 1528C, the NW 1505, and the epitaxial structure 1528F; the ROM cell 1640 is formed based on the epitaxial structure 1528D, the NW 1505, and the epitaxial structure 1528F; and the ROM cell 1650 is formed based on the epitaxial structure 1528E, the NW 1505, and the epitaxial structure 1528F.

Specifically, the epitaxial structure 1528A and the epitaxial structure 1528F (together with the NW 1505) can serve as the positive terminal and the negative terminal of the ROM cell 1610; the epitaxial structure 1528B and the epitaxial structure 1528F (together with the NW 1505) can serve as the positive terminal and the negative terminal of the ROM cell 1620; the epitaxial structure 1528C and the epitaxial structure 1528F (together with the NW 1505) can serve as the positive terminal and the negative terminal of the ROM cell 1630; the epitaxial structure 1528D and the epitaxial structure 1528F (together with the NW 1505) can serve as the positive terminal and the negative terminal of the ROM cell 1640; and the epitaxial structure 1528E and the epitaxial structure 1528F (together with the NW 1505) can serve as the positive terminal and the negative terminal of the ROM cell 1650.

With no VD formed between the M0 track 1544 (connected to the word line WL0) and the MD 1530A, the ROM cell 1610 can be formed as a disconnected diode. For example, the MD 1530A is electrically isolated from the M0 track 1544 or the word line WL0 through no VD being formed. Similarly, the ROM cell 1640 can be formed as a disconnected diode, given that no VD formed between the MD 1530D and the M0 track 1550 (connected to the word line WL3). On the other hand, the epitaxial structures 1528B, 1528C, and 1528E are coupled to the word lines WL1 (through M0 track 1546 and VD 1539), WL2 (through M0 track 1548 and VD 1539), and WL4 (through M0 track 1552 and VD 1539), respectively, thereby forming the ROM cells 1620, 1630, and 1650 as connected diodes, respectively. In some embodiments, the disconnected diode may be associated with logic 0, and the connected diode may be associated with logic 1. Consequently, upon being formed, the ROM cells 1610, 1620, 1630, 1640, and 1650 can be programmed with logic 0, logic 1, logic 1, logic 0, and logic 1, respectively.

Referring next to FIGS. 17 and 18, the cross-sectional view cut along line B-B′ (or epitaxial structure 1528A in FIG. 15) and the cross-sectional view cut along line C-C′ (or epitaxial structure 1528C in FIG. 15) are shown, respectively. In FIG. 17, with the NW 1505 electrically coupled to the common bit line BL through the epitaxial structure 1528F, MD 1530F, and corresponding VD 1539 (FIG. 16), the epitaxial structure 1528A is electrically decoupled from the word line WL0 through no VD being formed. Further, the epitaxial structure 1528A can be in direct contact with the NW 1505. In some embodiments, the MD 1530A may be electrically isolated from the NW 1505 with the dielectric layer 1510. In FIG. 18, with the NW 1505 electrically coupled to the common bit line BL through the epitaxial structure 1528F, MD 1530F, and corresponding VD 1539 (FIG. 16), the epitaxial structure 1528C is electrically coupled to the word line WL2 through the MD 1530C and corresponding VD 1539. Further, the epitaxial structure 1528C can be in direct contact with the NW 1505. In some embodiments, the MD 1530C may be electrically isolated from the NW 1505 with another dielectric layer 1510.

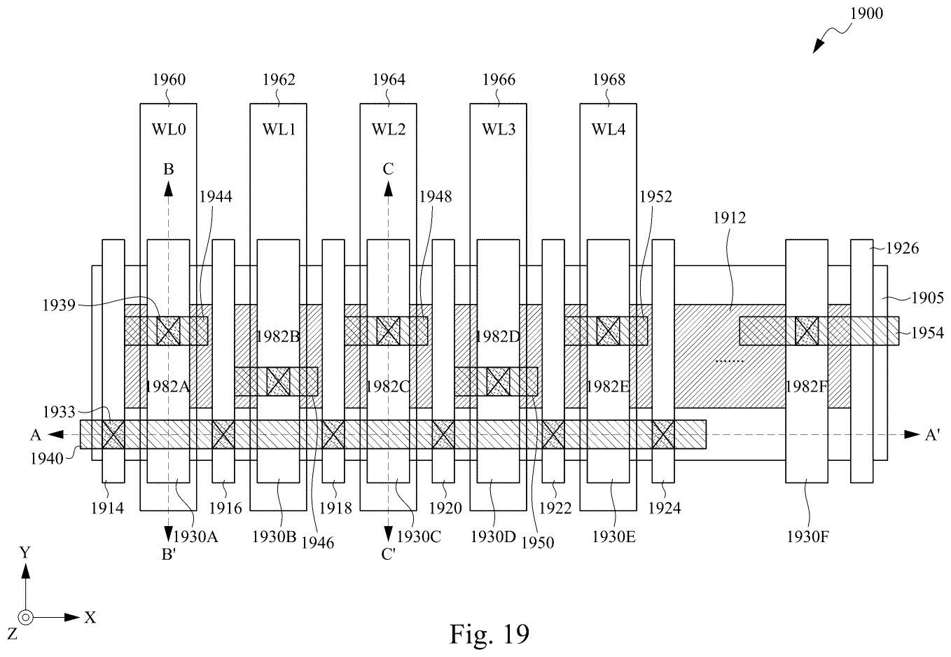

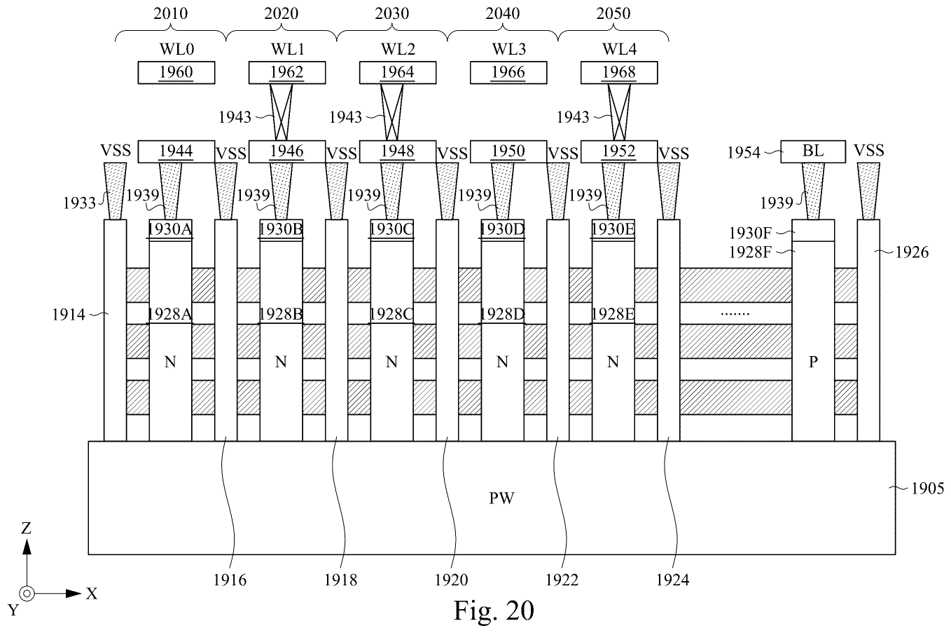

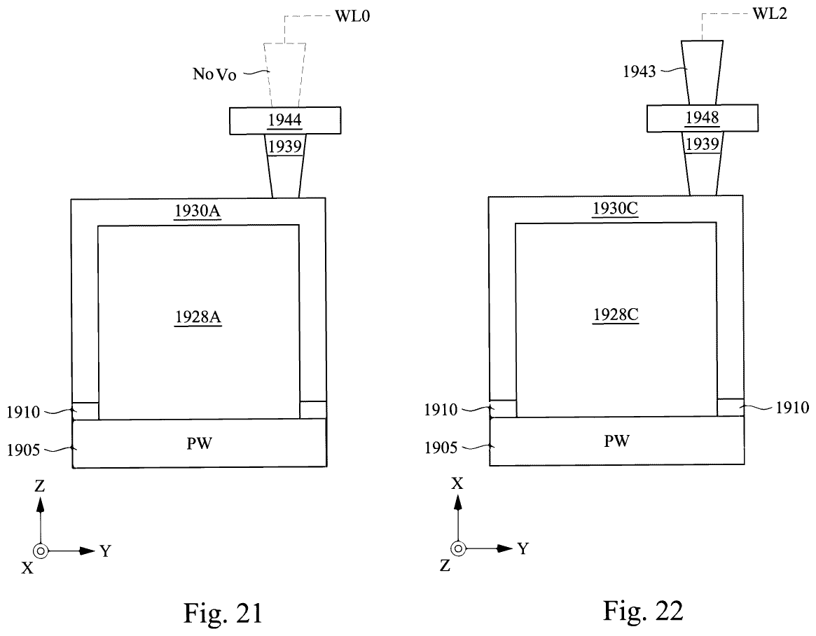

FIG. 19 illustrates an example layout 1900 configured to form (or program) a memory array including a plural number of ROM cells (e.g., 5 ROM cells) that are arranged along the X-direction. In some embodiments, these ROM cells can be programmed with respective logic states based on processing techniques. FIG. 20, FIG. 21, and FIG. 22 illustrate cross-sectional views of the memory array formed based on the layout 1900, respectively.

For example, FIG. 20 illustrates a hybrid cross-sectional view of the memory array cut along or parallel with line A-A′ (e.g., the X-direction), FIG. 21 illustrates a cross-sectional view of the memory array cut along line B-B′ (e.g., the Y-direction), and FIG. 22 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 19 and the corresponding cross-sectional views of FIGS. 20-22 are provided merely for illustrative purposes, and are not intended to limit the scope of the present disclosure.

Referring first to FIG. 19, the layout 1900 includes patterns for forming a well 1905, one or more dielectric layers 1910 (better illustrated in the cross-sectional views of FIGS. 21-22), an active region 1912, and gate structures 1914, 1916, 1918, 1920, 1922, 1924 . . . 1926, respectively. In some embodiments, the well 1905 and the active region 1912 can extend along a first lateral direction, e.g., the X-direction, while the gate structures 1914 to 1926 can each extend along a second lateral direction perpendicular to the first lateral direction, e.g., the Y-direction. As such, the gate structures 1914 to 1926 can each traverse the active region 1912. The gate structures 1914 to 1926 can each correspond to an active (e.g., metal) gate structure. For example, the gate structure 1914 to 1926 can each formed as a polysilicon gate structure (sometimes referred to as a dummy gate structure), and then be replaced with a corresponding metal gate structure (sometimes referred to as an active gate structure). The well 1905, the dielectric layer(s) 1910, the active region 1912, and the gate structures 1914 to 1926, which are formed along the major surface of a substrate, are sometimes referred to as part of front-end-of-line (FEOL) processing.

In the example of FIGS. 19-22, the ROM cells of the memory array are each formed as a diode, with its BL and WL being connected to or disconnected from each other, based on a gate-all-around (GAA) transistor structure. However, the ROM cells of the memory array (formed by the layout 1900) can be formed as any of various other transistor structure while remaining within the scope of the present disclosure. With the GAA transistor structure, the active region 1912 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 19-20, epitaxial structures 1928A, 1928B, 1928C, 1928D, 1928E . . . 1928F (formed in the active region 1912) and the gate structures 1914 to 1926 can be alternately arranged along the X-direction. For example, along the X-direction, the epitaxial structure 1928A is interposed between the gate structures 1914 and 1916, the epitaxial structure 1928B is interposed between the gate structures 1916 and 1918, the epitaxial structure 1928C is interposed between the gate structures 1918 and 1920, the epitaxial structure 1928D is interposed between the gate structures 1920 and 1922, the epitaxial structure 1928E is interposed between the gate structures 1922 and 1924, and the epitaxial structure 1928F is interposed between a non-shown gate structure and the gate structure 1926. Further, to program the ROM cells with different logic states, a first group of the epitaxial structures (e.g., 1928A, 1928D) can be electrically isolated from upper interconnect structures functioning as respective word lines WLs, and a second group of the epitaxial structures (e.g., 1928B, 1928C, 1928E) can be electrically coupled to upper interconnect structures functioning as respective word lines WLs. In some embodiments, all the epitaxial structures 1928A to 1928F may be in contact with the well 1905.

According to some embodiments of the present disclosure, the well 1905 is formed with a first conductive type (e.g., p-type), which is sometimes referred to as a p-well (PW) 1905, while one of the epitaxial structures (e.g., 1928F) is formed with the same first conductive type (p-type) and the rest of the epitaxial structures (e.g., 1928A-E) are formed with a second, opposite conductive type (e.g., n-type). The epitaxial structure 1928F can have a higher doping concentration than the PW 1905. All the gate structures 1914 to 1926 can be electrically coupled to a supply voltage (e.g., VSS) such as, for example, to turn off the channels of the transistors. Similar to the ROM cell 100 (FIG. 1), the p-type epitaxial structure 1928F, together with the PW 1905, can operatively serve as a common positive terminal for the ROM cells, while each of the n-type epitaxial structures 1928A-E can operatively serve as a negative terminal for the respective ROM cell. As will be discussed below, the common positive terminal of the ROM cells can be coupled to a common bit line BL, and the negative terminal of each of the ROM cells can be selectively coupled to a respective word line WL. Further, the negative terminal of each of the ROM cells can be electrically coupled to or isolated from the respective word line WL, based on a desired logic state to be programmed to the ROM cell.

The layout 1900 further includes patterns for forming source/drain contact structures (each sometimes referred to as an MD) 1930A, 1930B, 1930C, 1930D, 1930E . . . 1930F, respectively. Generally, each of the MDs 1930A to 1930F is disposed above a corresponding one of the epitaxial structures 1928A to 1928F, as shown in FIG. 20. The MDs 1930A to 1930F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 1900 further includes patterns for forming a number of VDs 1939 to electrically connect the underlying MD to an above interconnect structure. In the example of FIGS. 19-20, the epitaxial structures 1928A to 1928F are connected to the respective VDs 1939.

The layout 1900 further includes patterns for forming a number of other via structures 1933 (each sometimes referred to as a VG) to electrically connect a corresponding underlying gate structure to an above interconnect structure. The layout 1900 further includes patterns for forming those interconnect structures in the upper metallization layers, which will be discussed as follows. The MDs 1939A-F, VGs 1933, and VDs 1939 are sometimes referred to as part of middle-end-of-line (MEOL) processing, and the interconnect structures in the metallization layers are sometimes referred to as part of back-end-of-line (BEOL) processing.

In the illustrative example of FIGS. 19-20, the gate structures 1914 to 1926 can be coupled to an interconnect structure 1940 formed in a bottommost one of the metallization layers M0 (sometimes referred to as an M0 track 1940) through respective VGs 1933. In some embodiments, the M0 track 1940 is configured to carry (or coupled to) the VSS, which electrically ties the gate structures 1914 to 1926 to the VSS. The MDs 1928A to 1928F can be coupled to other M0 tracks 1944, 1946, 1948, 1950, 1952, and 1954 through the respective VDs 1939. The M0 tracks 1946, 1948, and 1952 can be further coupled to respective interconnect structures, 1962, 1964, and 1968, in a next bottommost one of the metallization layers M1 (sometimes referred to as M1 track 1962, M1 track 1964, and M1 track 1968) through respective via structures 1943, while the M0 track 1944 is isolated from the M1 track 1960 (e.g., with no via structure 1943 being formed therebetween) and the M0 track 1950 is isolated from the M1 track 1966 (e.g., with no via structure 1943 being formed therebetween). The via structure 1943 is sometimes referred to as a V0. In some embodiments, the M1 track 1960, M1 track 1962, M1 track 1964, M1 track 1966, and M1 track 1968 are configured as (or coupled to) word lines, WL0, WL1, WL2, WL3, and WL4, respectively, with the M0 track 1954 configured as (or coupled to) a common bit line BL.

In some embodiments, ROM cells 2010, 2020, 2030, 2040, and 2050 (FIG. 20) can be programmed, upon the above-described interconnect structures (e.g., the M0 tracks 1940-1954, the M1 tracks 1960-1968) being formed. For example, the ROM cell 2010 is formed based on the epitaxial structure 1928A, the PW 1905, and the epitaxial structure 1928F; the ROM cell 2020 is formed based on the epitaxial structure 1928B, the PW 1905, and the epitaxial structure 1928F; the ROM cell 2030 is formed based on the epitaxial structure 1928C, the PW 1905, and the epitaxial structure 1928F; the ROM cell 2040 is formed based on the epitaxial structure 1928D, the PW 1905, and the epitaxial structure 1928F; and the ROM cell 2050 is formed based on the epitaxial structure 1928E, the PW 1905, and the epitaxial structure 1928F.

Specifically, the epitaxial structure 1928A and the epitaxial structure 1928F (together with the PW 1905) can serve as the negative terminal and the positive terminal of the ROM cell 2010; the epitaxial structure 1928B and the epitaxial structure 1928F (together with the PW 1905) can serve as the negative terminal and the positive terminal of the ROM cell 2020; the epitaxial structure 1928C and the epitaxial structure 1928F (together with the PW 1905) can serve as the negative terminal and the positive terminal of the ROM cell 2030; the epitaxial structure 1928D and the epitaxial structure 1928F (together with the PW 1905) can serve as the negative terminal and the positive terminal of the ROM cell 2040; and the epitaxial structure 1928E and the epitaxial structure 1928F (together with the PW 1905) can serve as the negative terminal and the positive terminal of the ROM cell 2050.

With no V0 formed between the M0 track 1944 and the M1 track 1960 (functioning as the word line WL0), the ROM cell 2010 can be formed as a disconnected diode. For example, the MD 1930A is electrically isolated from the word line WL0 through no V0 being formed. Similarly, the ROM cell 2040 can be formed as a disconnected diode, given that no V0 formed between the M0 track 1950 and the M1 track 1966 (functioning as the word line WL3). On the other hand, the epitaxial structures 1928B, 1928C, and 1928E are coupled to the word lines WL1 (through M0 track 1946), WL2 (through M0 track 1948), and WL4 (through M0 track 1952), respectively, thereby forming the ROM cells 2020, 2030, and 2050 as connected diodes, respectively. In some embodiments, the disconnected diode may be associated with logic 0, and the connected diode may be associated with logic 1. Consequently, upon being formed, the ROM cells 2010, 2020, 2030, 2040, and 2050 can be programmed with logic 0, logic 1, logic 1, logic 0, and logic 1, respectively.

Referring next to FIGS. 21 and 22, the cross-sectional view cut along line B-B′ (or epitaxial structure 1928A in FIG. 19) and the cross-sectional view cut along line C-C′ (or epitaxial structure 1928C in FIG. 19) are shown, respectively. In FIG. 21, with the PW 1905 electrically coupled to the common bit line BL through the epitaxial structure 1928F, MD 1930F, and corresponding VD 1939 (FIG. 20), the epitaxial structure 1928A is electrically decoupled from the word line WL0 through no V0 being formed. Further, the epitaxial structure 1928A can be in direct contact with the PW 1905. In some embodiments, the MD 1030A may be electrically isolated from the PW 1905 with the dielectric layer 1910. In FIG. 22, with the PW 1905 electrically coupled to the common bit line BL through the epitaxial structure 1928F, MD 1930F, and corresponding VD 1939 (FIG. 20), the epitaxial structure 1928C is electrically coupled to the word line WL2 through the MD 1930C, corresponding VD 1939, M1 track 1948, and corresponding V0 1943. Further, the epitaxial structure 1928C can be in direct contact with the PW 1905. In some embodiments, the MD 1930C may be electrically isolated from the PW 1905 with another dielectric layer 1910.

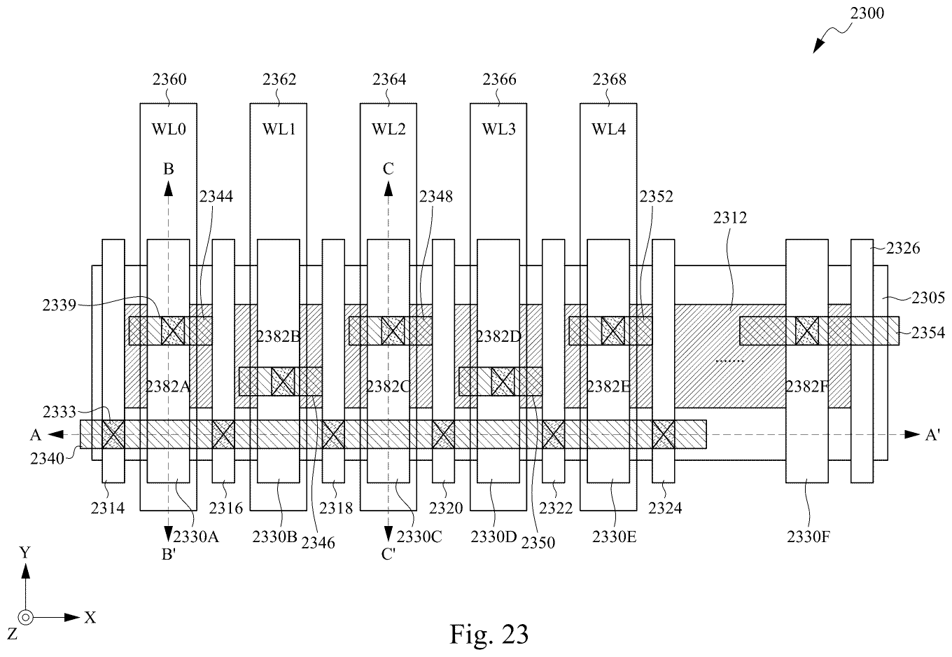

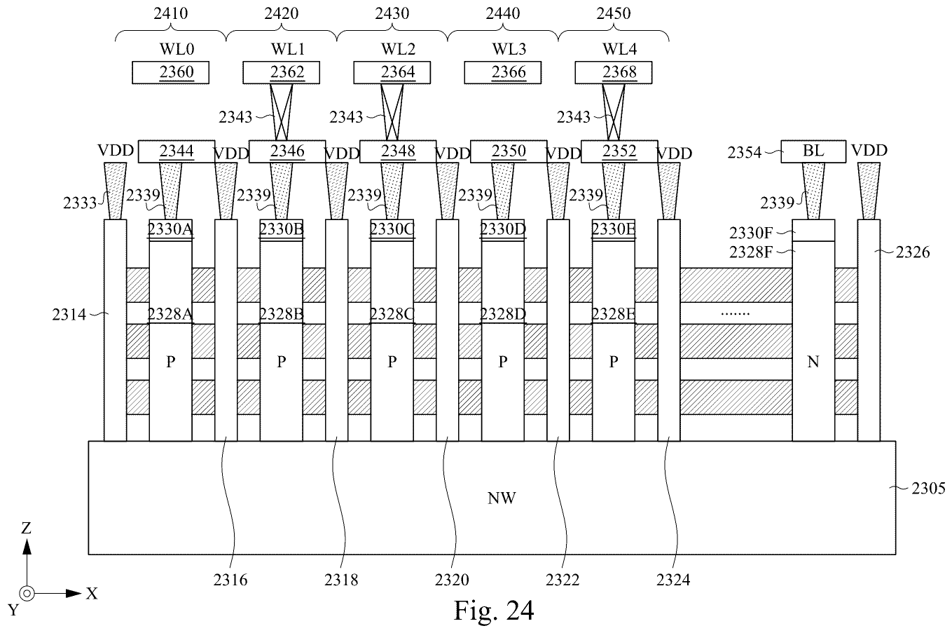

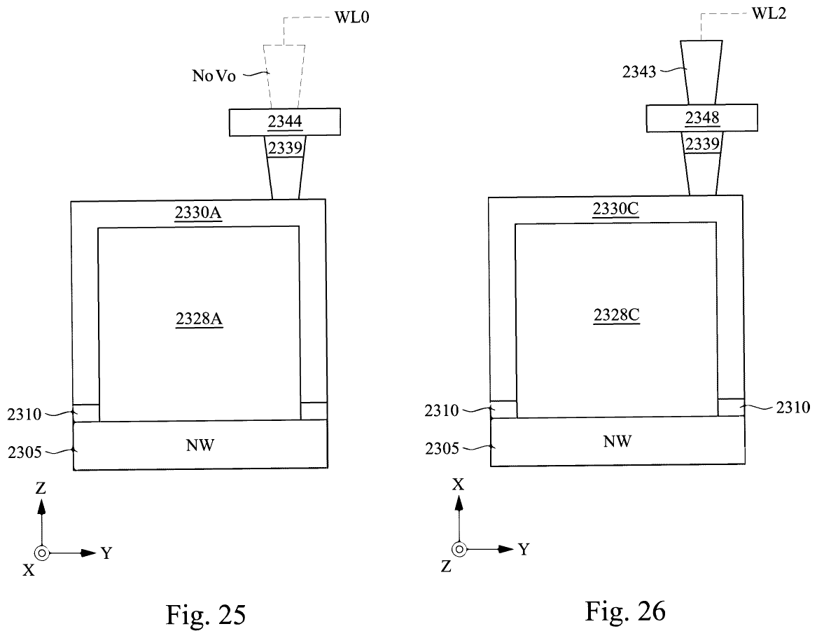

FIG. 23 illustrates an example layout 2300 configured to form (or program) a memory array including a plural number of ROM cells (e.g., 5 ROM cells) that are arranged along the X-direction. In some embodiments, these ROM cells can be programmed with respective logic states based on processing techniques. FIG. 24, FIG. 25, and FIG. 26 illustrate cross-sectional views of the memory array formed based on the layout 2300, respectively.

For example, FIG. 23 illustrates a hybrid cross-sectional view of the memory array cut along or parallel with line A-A′ (e.g., the X-direction), FIG. 24 illustrates a cross-sectional view of the memory array cut along line B-B′ (e.g., the Y-direction), and FIG. 25 illustrates a cross-sectional view of the memory array cut along line C-C′ (e.g., the Y-direction). As disclosed herein, the term “hybrid cross-sectional view” refers to a combination of multiple cross-sectional views cut along the same direction and overlapped with each other. It should be understood that the layout of FIG. 23 and the corresponding cross-sectional views of FIGS. 24-26 are provided merely for illustrative purposes, and are not intended to limit the scope of the present disclosure.

Referring first to FIG. 23, the layout 2300 includes patterns for forming a well 2305, one or more dielectric layers 2310 (better illustrated in the cross-sectional views of FIGS. 25-26), an active region 2312, and gate structures 2314, 2316, 2318, 2320, 2322, 2324. 2326, respectively. In some embodiments, the well 2305 and the active region 2312 can extend along a first lateral direction, e.g., the X-direction, while the gate structures 2314 to 2326 can each extend along a second lateral direction perpendicular to the first lateral direction, e.g., the Y-direction. As such, the gate structures 2314 to 2326 can each traverse the active region 2312. The gate structures 2314 to 2326 can each correspond to an active (e.g., metal) gate structure. For example, the gate structure 2314 to 2326 can each formed as a polysilicon gate structure (sometimes referred to as a dummy gate structure), and then be replaced with a corresponding metal gate structure (sometimes referred to as an active gate structure). The well 2305, the dielectric layer(s) 2310, the active region 2312, and the gate structures 2314 to 2326, which are formed along the major surface of a substrate, are sometimes referred to as part of front-end-of-line (FEOL) processing.

In the example of FIGS. 23-26, the ROM cells of the memory array are each formed as a diode, with its BL and WL being connected to or disconnected from each other, based on a gate-all-around (GAA) transistor structure. However, the ROM cells of the memory array (formed by the layout 2300) can be formed as any of various other transistor structure while remaining within the scope of the present disclosure. With the GAA transistor structure, the active region 2312 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 23-24, epitaxial structures 2328A, 2328B, 2328C, 2328D, 2328E . . . 2328F (formed in the active region 2312) and the gate structures 2314 to 2326 can be alternately arranged along the X-direction. For example, along the X-direction, the epitaxial structure 2328A is interposed between the gate structures 2314 and 2316, the epitaxial structure 2328B is interposed between the gate structures 2316 and 2318, the epitaxial structure 2328C is interposed between the gate structures 2318 and 2320, the epitaxial structure 2328D is interposed between the gate structures 2320 and 2322, the epitaxial structure 2328E is interposed between the gate structures 2322 and 2324, and the epitaxial structure 2328F is interposed between a non-shown gate structure and the gate structure 2326. Further, to program the ROM cells with different logic states, a first group of the epitaxial structures (e.g., 2328A, 2328D) can be electrically isolated from upper interconnect structures functioning as respective word lines WLs, and a second group of the epitaxial structures (e.g., 2328B, 2328C, 2328E) can be electrically coupled to upper interconnect structures functioning as respective word lines WLs. In some embodiments, all the epitaxial structures 2328A to 2328F may be in contact with the well 2305.

According to some embodiments of the present disclosure, the well 2305 is formed with a first conductive type (e.g., n-type), which is sometimes referred to as an n-well (NW) 2305, while one of the epitaxial structures (e.g., 2328F) is formed with the same first conductive type (n-type) and the rest of the epitaxial structures (e.g., 2328A-E) are formed with a second, opposite conductive type (e.g., p-type). The epitaxial structure 2328F can have a higher doping concentration than the PW 2305. All the gate structures 2314 to 2326 can be electrically coupled to a supply voltage (e.g., VDD) such as, for example, to turn off the channels of the transistors. Similar to the ROM cell 200 (FIG. 2), the p-type epitaxial structure 2328F, together with the NW 2305, can operatively serve as a common negative terminal for the ROM cells, while each of the p-type epitaxial structures 2328A-E can operatively serve as a positive terminal for the respective ROM cell. As will be discussed below, the common negative terminal of the ROM cells can be coupled to a common bit line BL, and the positive terminal of each of the ROM cells can be selectively coupled to a respective word line WL. Further, the positive terminal of each of the ROM cells can be electrically coupled to or isolated from the respective word line WL, based on a desired logic state to be programmed to the ROM cell.

The layout 2300 further includes patterns for forming source/drain contact structures (each sometimes referred to as an MD) 2330A, 2330B, 2330C, 2330D, 2330E . . . 2330F, respectively. Generally, each of the MDs 2330A to 2330F is disposed above a corresponding one of the epitaxial structures 2328A to 2328F, as shown in FIG. 24. The MDs 2330A to 2330F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 2300 further includes patterns for forming a number of VDs 2339 to electrically connect the underlying MD to an above interconnect structure. In the example of FIGS. 23-24, the epitaxial structures 2328A to 2328F are connected to the respective VDs 2339.

The layout 2300 further includes patterns for forming a number of other via structures 2333 (each sometimes referred to as a VG) to electrically connect a corresponding underlying gate structure to an above interconnect structure. The layout 2300 further includes patterns for forming those interconnect structures in the upper metallization layers, which will be discussed as follows. The MDs 2339A-F, VGs 2333, and VDs 2339 are sometimes referred to as part of middle-end-of-line (MEOL) processing, and the interconnect structures in the metallization layers are sometimes referred to as part of back-end-of-line (BEOL) processing.

In the illustrative example of FIGS. 23-24, the gate structures 2314 to 2326 can be coupled to an interconnect structure 2340 formed in a bottommost one of the metallization layers M0 (sometimes referred to as an M0 track 2340) through respective VGs 2333. In some embodiments, the M0 track 2340 is configured to carry (or coupled to) the VDD, which electrically ties the gate structures 2314 to 2326 to the VDD. The MDs 2328A to 2328F can be coupled to other M0 tracks 2344, 2346, 2348, 2350, 2352, and 2354 through the respective VDs 2339. The M0 tracks 2346, 2348, and 2352 can be further coupled to respective interconnect structures, 2362, 2364, and 2368, in a next bottommost one of the metallization layers M1 (sometimes referred to as M1 track 2362, M1 track 2364, and M1 track 2368) through respective via structures 2343, while the M0 track 2344 is isolated from the M1 track 2360 (e.g., with no via structure 2343 being formed therebetween) and the M0 track 2350 is isolated from the M1 track 2366 (e.g., with no via structure 2343 being formed therebetween). The via structure 2343 is sometimes referred to as a V0. In some embodiments, the M1 track 2360, M1 track 2362, M1 track 2364, M1 track 2366, and M1 track 2368 are configured as (or coupled to) word lines, WL0, WL1, WL2, WL3, and WL4, respectively, with the M0 track 2354 configured as (or coupled to) a common bit line BL.

In some embodiments, ROM cells 2410, 2420, 2430, 2440, and 2450 (FIG. 24) can be programmed, upon the above-described interconnect structures (e.g., the M0 tracks 2340-2354, the M1 tracks 2360-2368) being formed. For example, the ROM cell 2410 is formed based on the epitaxial structure 2328A, the NW 2305, and the epitaxial structure 2328F; the ROM cell 2420 is formed based on the epitaxial structure 2328B, the NW 2305, and the epitaxial structure 2328F; the ROM cell 2430 is formed based on the epitaxial structure 2328C, the NW 2305, and the epitaxial structure 2328F; the ROM cell 2440 is formed based on the epitaxial structure 2328D, the NW 2305, and the epitaxial structure 2328F; and the ROM cell 2450 is formed based on the epitaxial structure 2328E, the NW 2305, and the epitaxial structure 2328F.

Specifically, the epitaxial structure 2328A and the epitaxial structure 2328F (together with the NW 2305) can serve as the positive terminal and the negative terminal of the ROM cell 2410; the epitaxial structure 2328B and the epitaxial structure 2328F (together with the NW 2305) can serve as the negative terminal and the positive terminal of the ROM cell 2420; the epitaxial structure 2328C and the epitaxial structure 2398F (together with the NW 2305) can serve as the negative terminal and the positive terminal of the ROM cell 2430; the epitaxial structure 2328D and the epitaxial structure 2328F (together with the NW 2305) can serve as the negative terminal and the positive terminal of the ROM cell 2440; and the epitaxial structure 2328E and the epitaxial structure 2328F (together with the NW 2305) can serve as the negative terminal and the positive terminal of the ROM cell 2450.

With no V0 formed between the M0 track 2344 and the M1 track 2360 (functioning as the word line WL0), the ROM cell 2410 can be formed as a disconnected diode. For example, the MD 2330A is electrically isolated from the word line WL0 through no V0 being formed. Similarly, the ROM cell 2440 can be formed as a disconnected diode, given that no V0 formed between the M0 track 2350 and the M1 track 2366 (functioning as the word line WL3). On the other hand, the epitaxial structures 2328B, 2328C, and 2328E are coupled to the word lines WL1 (through M0 track 2346), WL2 (through M0 track 2348), and WL4 (through M0 track 2352), respectively, thereby forming the ROM cells 2420, 2430, and 2450 as connected diodes, respectively. In some embodiments, the disconnected diode may be associated with logic 0, and the connected diode may be associated with logic 1. Consequently, upon being formed, the ROM cells 2410, 2420, 2430, 2440, and 2450 can be programmed with logic 0, logic 1, logic 1, logic 0, and logic 1, respectively.

Referring next to FIGS. 25 and 26, the cross-sectional view cut along line B-B′ (or epitaxial structure 2328A in FIG. 23) and the cross-sectional view cut along line C-C′ (or epitaxial structure 2328C in FIG. 23) are shown, respectively. In FIG. 25, with the NW 2305 electrically coupled to the common bit line BL through the epitaxial structure 2328F, MD 2330F, and corresponding VD 2339 (FIG. 25), the epitaxial structure 2328A is electrically decoupled from the word line WL0 through no V0 being formed. Further, the epitaxial structure 2328A can be in direct contact with the NW 2305. In some embodiments, the MD 2330A may be electrically isolated from the NW 2305 with the dielectric layer 2310. In FIG. 26, with the NW 2305 electrically coupled to the common bit line BL through the epitaxial structure 2328F, MD 2330F, and corresponding VD 2339 (FIG. 24), the epitaxial structure 2328C is electrically coupled to the word line WL2 through the MD 2330C, corresponding VD 2339, M1 track 2348, and corresponding V0 2343. Further, the epitaxial structure 2328C can be in direct contact with the NW 2305. In some embodiments, the MD 2330C may be electrically isolated from the NW 2305 with another dielectric layer 2310.

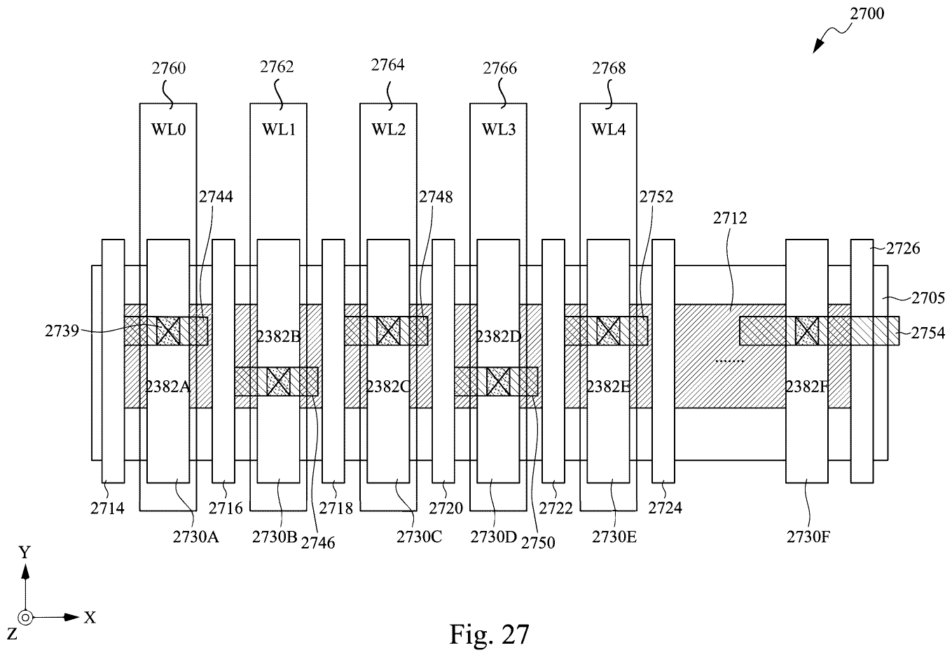

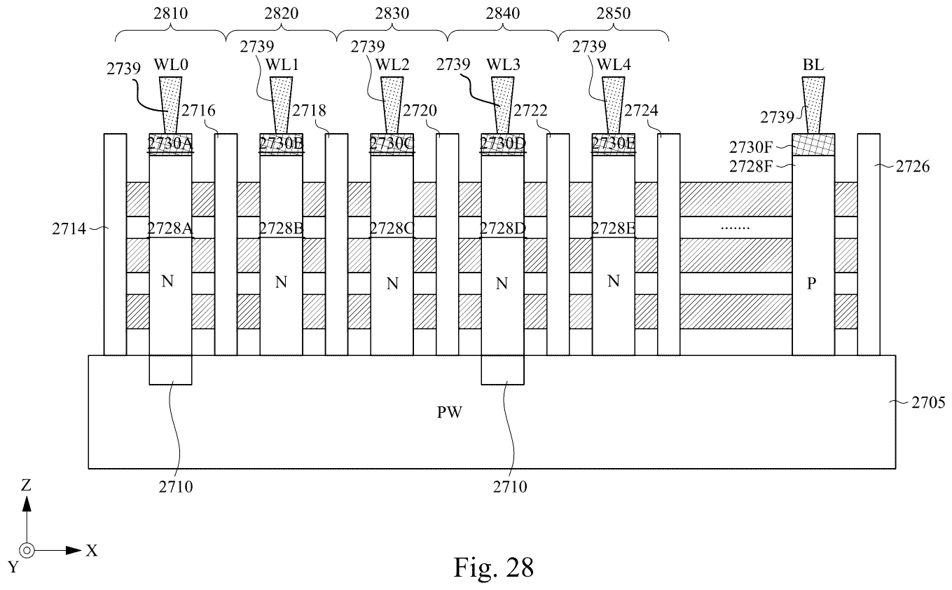

FIG. 27 illustrates an example layout 2700 configured to form (or program) a memory array including a plural number of ROM cells (e.g., 5 ROM cells) that are arranged along the X-direction. In some embodiments, these ROM cells can be programmed with respective logic states based on processing techniques. FIG. 28 illustrates a cross-sectional view of the memory array formed based on the layout 2700. For example, FIG. 28 illustrates a hybrid cross-sectional view of the memory array cut along or parallel with line A-A′ (e.g., the X-direction). As disclosed herein, the term “hybrid cross-sectional view” refers to a combination of multiple cross-sectional views cut along the same direction and overlapped with each other. It should be understood that the layout of FIG. 27 and the corresponding cross-sectional view of FIG. 28 are provided merely for illustrative purposes, and are not intended to limit the scope of the present disclosure.

Referring first to FIG. 27, the layout 2700 includes patterns for forming a well 2705, one or more dielectric layers 2710 (better illustrated in the cross-sectional views of FIG. 28), an active region 2712, and gate structures 2714, 2716, 2718, 2720, 2722, 2724 . . . 2726, respectively. In some embodiments, the well 2705 and the active region 2712 can extend along a first lateral direction, e.g., the X-direction, while the gate structures 2714 to 2726 can each extend along a second lateral direction perpendicular to the first lateral direction, e.g., the Y-direction. As such, the gate structures 2714 to 2726 can each traverse the active region 2712. The gate structures 2714 to 2726 can each correspond to a dummy (e.g., dielectric) gate structure. For example, the gate structure 2714 to 2726 can each formed as a polysilicon gate structure, and then be replaced with a corresponding dielectric gate structure. The well 2705, the dielectric layer(s) 2710, the active region 2712, and the gate structures 2714 to 2726, which are formed along the major surface of a substrate, are sometimes referred to as part of front-end-of-line (FEOL) processing.

In the example of FIGS. 27-28, the ROM cells of the memory array are each formed as a diode, with its BL and WL being connected to or disconnected from each other, based on a gate-all-around (GAA) transistor structure. However, the ROM cells of the memory array (formed by the layout 2700) can be formed as any of various other transistor structure while remaining within the scope of the present disclosure. With the GAA transistor structure, the active region 2712 can be formed of a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by each of the gate structure remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures of the transistor, and a portion of the gate structure that overlays (e.g., straddles) the remaining portions of the semiconductor structures can be configured as a gate terminal of the transistor.

In FIGS. 27-28, epitaxial structures 2728A, 2728B, 2728C, 2728D, 2728E. 2728F (formed in the active region 2712) and the gate structures 2714 to 2726 can be alternately arranged along the X-direction. For example, along the X-direction, the epitaxial structure 2728A is interposed between the gate structures 2714 and 2716, the epitaxial structure 2728B is interposed between the gate structures 2716 and 2718, the epitaxial structure 2728C is interposed between the gate structures 2718 and 2720, the epitaxial structure 2728D is interposed between the gate structures 2720 and 2722, the epitaxial structure 2728E is interposed between the gate structures 2722 and 2724, and the epitaxial structure 2728F is interposed between a non-shown gate structure and the gate structure 2726. Further, to program the ROM cells with different logic states, a first group of the epitaxial structures (e.g., 2728A, 328D) can be physically separated (and/or electrically isolated) from the well 2705 with the dielectric layers 2710, respectively, and a second group of the epitaxial structures (e.g., 2728B, 2728C, 2728E) can be in direct contact with the well 2705.

According to some embodiments of the present disclosure, the well 2705 is formed with a first conductive type (e.g., p-type), which is sometimes referred to as a p-well (PW) 2705, while one of the epitaxial structures (e.g., 2728F) is formed with the same first conductive type (p-type) and the rest of the epitaxial structures (e.g., 2728A-E) are formed with a second, opposite conductive type (e.g., n-type). The epitaxial structure 2728F can have a higher doping concentration than the 27 W 305. The gate structures 2714 to 2726 may not be necessarily coupled to a supply voltage (e.g., VSS). Similar to the ROM cell 100 (FIG. 1), the p-type epitaxial structure 2728F, together with the PW 2705, can operatively serve as a common positive terminal for the ROM cells, while each of the n-type epitaxial structures 2728A-E can operatively serve as a negative terminal for the respective ROM cell. As will be discussed below, the common positive terminal of the ROM cells can be coupled to a common bit line BL, and the negative terminal of each of the ROM cells can be coupled to a respective word line WL. Further, the positive terminal and the negative terminal of each of the ROM cells can be electrically coupled to or isolated from each other, based on a desired logic state to be programmed to the ROM cell.

The layout 2700 further includes patterns for forming source/drain contact structures (each sometimes referred to as an MD) 2730A, 2730B, 2730C, 2730D, 2730E . . . 2730F, respectively. Generally, each of the MDs 2730A to 2730F is disposed above a corresponding one of the epitaxial structures 2728A to 2728F, as shown in FIG. 28. The MDs 2730A to 2730F (formed of a metal material, e.g., copper, tungsten, cobalt, etc.) are each configured to electrically couple the corresponding epitaxial structure to an interconnect structure formed in an upper metallization layer through a via structure (sometimes referred to as a VD). For example, the layout 2700 further includes patterns for forming a number of VDs 2739 to electrically connect the underlying MD to an above interconnect structure. The layout 2700 further includes patterns for forming those interconnect structures in the upper metallization layers, which will be discussed as follows. The MDs 2739A-F, and VDs 2739 are sometimes referred to as part of middle-end-of-line (MEOL) processing, and the interconnect structures in the metallization layers are sometimes referred to as part of back-end-of-line (BEOL) processing.

In the illustrative example of FIGS. 27-28, the gate structures 314 to 326 may not be necessarily coupled to an interconnect structure formed in a bottommost one of the metallization layers M0 (sometimes referred to as an M0 track). The MDs 2728A to 2728F can be coupled to M0 tracks 2744, 2746, 2748, 2750, 2752, and 2754 through the respective VDs 2739. The M0 tracks 2744, 2746, 2748, 2750, and 2752 can be further coupled to respective interconnect structures, 2760, 2762, 2764, 2766, and 2768, in a next bottommost one of the metallization layers MI (sometimes referred to as M1 track 2760, M1 track 2762, M1 track 2764, M1 track 2766, and M1 track 2768) through respective via structures. In some embodiments, the M1 track 2760, M1 track 2762, M1 track 2764, M1 track 2766, and M1 track 2768 are configured as (or coupled to) word lines, WL0, WL1, WL2, WL3, and WL4, respectively, with the M0 track 2754 configured as (or coupled to) a common bit line BL.

In some embodiments, ROM cells 2810, 2820, 2830, 2840, and 2850 (FIG. 28) can be programmed, upon the above-described interconnect structures (e.g., the M0 tracks 2740-2754, the M1 tracks 2760-2768) being formed. For example, the ROM cell 2810 is formed based on the epitaxial structure 2728A, one of the dielectric layers 2710, the PW 2705, and the epitaxial structure 2728F; the ROM cell 2820 is formed based on the epitaxial structure 2728B, the PW 2705, and the epitaxial structure 2728F; the ROM cell 2830 is formed based on the epitaxial structure 2728C, the PW 2705, and the epitaxial structure 2728F; the ROM cell 2840 is formed based on the epitaxial structure 2728D, another one of the dielectric layers 2710, the PW 2705, and the epitaxial structure 2728F; and the ROM cell 2850 is formed based on the epitaxial structure 2728E, the PW 2705, and the epitaxial structure 2728F.

Specifically, the epitaxial structure 2728A and the epitaxial structure 2728F (together with the PW 2705) can serve as the negative terminal and the positive terminal of the ROM cell 2810; the epitaxial structure 2728B and the epitaxial structure 2728F (together with the PW 2705) can serve as the negative terminal and the positive terminal of the ROM cell 2820; the epitaxial structure 2728C and the epitaxial structure 2728F (together with the PW 2705) can serve as the negative terminal and the positive terminal of the ROM cell 2830; the epitaxial structure 2728D and the epitaxial structure 2728F (together with the PW 2705) can serve as the negative terminal and the positive terminal of the ROM cell 2840; and the epitaxial structure 2728E and the epitaxial structure 2728F (together with the PW 2705) can serve as the negative terminal and the positive terminal of the ROM cell 2850.

With the dielectric layer 2710 interposed between the epitaxial structure 2728A and the PW 2705, the ROM cell 2810 can be formed as a disconnected diode. For example, the epitaxial structure 2728A and the PW 2705 are electrically isolated from each other with the dielectric layer 2710. Similarly, the ROM cell 2840 can be formed as a disconnected diode, given the dielectric layer 2710 interposed between the epitaxial structure 2728D and the PW 2705. Although in the cross-sectional view of FIG. 28, the dielectric layer 2710 is illustrated as having its sidewall aligned with the corresponding epitaxial structure (e.g., 2728A, 2728D), it should be appreciated that the dielectric layer 2710 can extend farther than the corresponding epitaxial structure (in the X-direction). On the other hand, each of the epitaxial structures 2728B, 2728C, and 2728E is in direct contact with the PW 2705, thereby forming the ROM cells 2820, 2830, and 2850 as connected diodes, respectively. In some embodiments, the disconnected diode may be associated with logic 0, and the connected diode may be associated with logic 1. Consequently, upon being formed, the ROM cells 2810, 2820, 2830, 2840, and 2850 can be programmed with logic 0, logic 1, logic 1, logic 0, and logic 1, respectively.

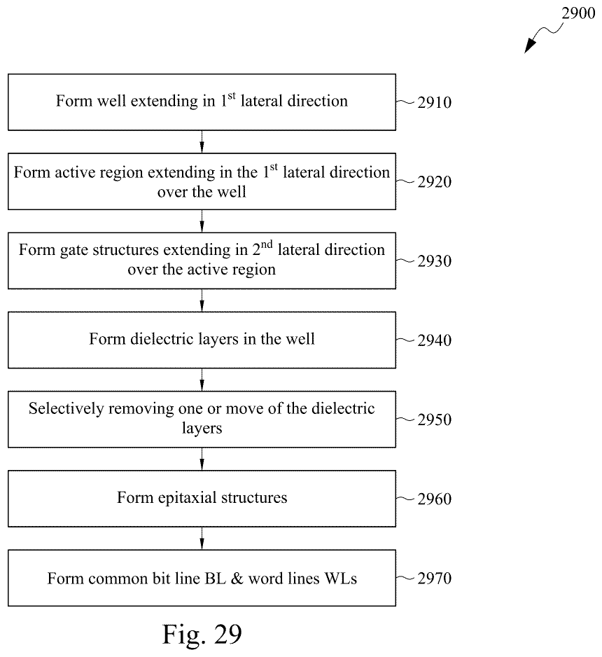

FIG. 29 illustrates a flow chart of an example method 2900 for forming a memory device (e.g., a memory array), in accordance with various embodiments of the present disclosure. In some embodiments, the memory device can be formed based on the layout 300 (FIGS. 3), 700 (FIGS. 7), 1100 (FIGS. 11), 1500 (FIGS. 15), 1900 (FIG. 19), or 2700 (FIG. 27), so as to have at least one of its memory cells programmed with a logic state different from other memory cells. Accordingly, the following discussion of the method 2900 may refer to some of the above figures. It should be noted that the method 2900 as shown in FIG. 29 is merely an example, and is not intended to limit the present disclosure. Thus, it is understood that the order of the operations of the method 2900 of FIG. 29 can be changed, for example, additional operations may be provided before, during, and after the method 2900, and that some operations may only be described briefly herein.

The method 2900 starts with operation 2910 of forming a well in a substrate that extends along a first lateral direction. In some embodiments, the substrate may be a silicon substrate. The substrate may include various layers, including conductive or insulating layers formed on a semiconductor substrate. The substrate may include various doping configurations depending on design requirements as is known in the art, e.g., a p-type silicon substrate. Using the layout 300 (FIG. 3) as a representative example, the well 305, with the p-type, can be defined to extend along the first lateral direction (e.g., the X-direction) in such a p-type substrate through one or more photolithography processes. Using the layout 700 (FIG. 7) as another representative example, the well 705, with an opposite conductive type to the p-type substrate, can be formed through one or more photolithography processes together with a doping process (e.g., ion implantation).

The method 2900 continues to operation 2920 of forming an active region over the well that extends along the first lateral direction. Continuing with the example of FIG. 3, the active region 312 can be formed as a stack of first semiconductor layers and second semiconductor layers alternately staked on top of one another. The stack (or each of the included first/second semiconductor layers) can extend along the same direction as the well 305, e.g., the X-direction. The first and second semiconductor layers can be alternately epitaxially grown from the substrate. The first and second semiconductor layers can have different composition, e.g., etching selectively to a certain etchant. For example, the first semiconductor layers may include silicon germanium (SiGe), and the second semiconductor layers may include silicon (Si). Further, the first semiconductor layers may later be replaced as one or more gate structures and the second semiconductor layers may be configured as channels of one or more GAA transistors.

As mentioned above, the currently disclosed ROM diodes can be formed based on other transistor structures, while remaining within the scope of the present disclosure. For example, the diodes can be formed based on a FinFET structure. In such an embodiment, the active region may be formed as one or more fin-like structures protruding from the substate, where the fin-like structures all extend along the first lateral direction and are spaced from one another along a second lateral direction perpendicular to the first lateral direction.

The method 2900 continues to operation 2930 of forming a plurality of gate structures over the active region, each of the gate structures extending along a second lateral direction perpendicular to the first lateral direction. Continuing with the above example of FIG. 3, the gate structures can be 314 to 326, extending in the Y-direction, can be formed over the active region 312. Each of the gate structures can be 314 to 326 can traverse the active region 312. In an example, the gate structures 314 to 326 may be first formed as dummy gate structures and later be replaced with metal gate structures, respectively.

The method 2900 continues to operation 2940 of forming a plurality of dielectric layers in the well. Still with the above example, after forming or defining the gate structures 312 to 326, portions of the active region 312 which are not overlaid or traversed by the gate structures 312 to 326 can be removed (e.g., etched). Further, respective portions in the well 305 vertically aligned with those non-overlaid portions of the active region 312 can also be removed (e.g. etched), followed by being filled with a dielectric material, in some embodiments. Consequently, a plural number of dielectric layers (e.g., 310), aligned with to-be-formed epitaxial structures (e.g., 328A to 328F), can be formed in the well 305. The dielectric material may include silicon oxide, silicon nitride, silicon oxynitride, fluorine-doped silicate glass (FSG), a low-k dielectric, combinations thereof, and/or other suitable materials.

The method 2900 continues to operation 2950 of selectively removing one or more of the dielectric layers. Still with the above example, after forming the dielectric layers 310 in the well 305, which can be alternately arranged with the gate structures 314 to 326 in the X-direction, one or more of the dielectric layers 310 can be removed to expose again the well 305. For instance, in FIG. 4, a majority portion of each of the dielectric layers 310 that are aligned with the epitaxial structures 328B-C, 328E, and 328F may be removed to expose the well 305. On the other hand, the dielectric layers 310 aligned with the epitaxial structures 328A and 328D may remain, so as to isolate the underlying well 305 from the above epitaxial structures 328A and 328D, respectively.

The method 2900 continues to operation 2960 of forming a plurality of epitaxial structures in the active region, each of the gate structures interposed between adjacent ones of the epitaxial structures. Still with the above example, after selectively removing one or more of the dielectric layers 310, the epitaxial structures 328A-F can be epitaxially grown from the overlaid second semiconductor layers (e.g., Si), or further from the exposed portions of the well 305. For example, the epitaxial structures 328B-C, 328E, and 328F can be epitaxially grown from the Si layers and the well 305, and the epitaxial structures 328A and 328D can be epitaxially grown from the Si layers. In some embodiments, one of the epitaxial structures (e.g., 328F) can be in-situ doped with the same conductive type as the well 305 during its epitaxial process by introducing doping species including: p-type dopants, such as boron or BF2, while the rest of the epitaxial structures (e.g., 328A-E) can be in-situ doped with the opposite conductive type to the well 305 during their epitaxial process n-type dopants, such as phosphorus or arsenic.

The method 2900 continues to operation 2970 of forming a plurality of first interconnect structures extending along the first lateral direction and a plurality of second interconnect structures extending along the second lateral direction, one of the first interconnect structures configured as a common bit line BL and the plurality of second interconnect structures respectively configured as word lines WLs. Continuing with the example of FIG. 3, a number of VGs 333 and a number of VDs 339 can be formed over the gate structures 314 to 326 and the epitaxial structures 328A to 328F, respectively.

In some embodiments, the VGs 333 can electrically couple the gate structures 314 to 326 to interconnect structure 340 carrying a supply voltage (e.g., VSS), so as to turn off the respective channels. The VDs 339 can electrically couple the epitaxial structures 328A-E to respective interconnect structures 360-368 functioning as the word lines WLs, with one of the VDs 339 configured to electrically couple the epitaxial structure 328F to interconnect structure 354 functioning as the common bit line BL. The interconnect structures 340 and 354 may be disposed in a bottommost one of metallization layers over the substrate (e.g., M0 layer) which extend in the X-direction, the interconnect structures 360-368 may be disposed in a next bottommost one of metallization layers over the substrate (e.g., M1 layer) which extend in the Y-direction.

In one aspect of the present disclosure, a memory device is disclosed. The memory device includes a well formed in a substrate and extending along a first lateral direction, wherein the well has a first conductive type; a plurality of epitaxial structures disposed over the well, wherein the plurality of epitaxial structures have a second conductive type opposite to the first conductive type; and a common epitaxial structure disposed over the well, wherein the common epitaxial structure has the first conductive type and is in contact the well. A first group of the plurality of epitaxial structures are each in contact with the well, and a second group of the plurality of epitaxial structures each have a bottom surface separated from the well with a corresponding dielectric layer.

In another aspect of the present disclosure, a memory device is disclosed. The memory device includes a well formed in a substrate and extending along a first lateral direction, wherein the well has a first conductive type; a plurality of epitaxial structures disposed over the well, wherein the plurality of epitaxial structures have a second conductive type opposite to the first conductive type; a plurality of gate structures extending along a second lateral direction perpendicular to the first lateral direction, wherein each of the plurality of epitaxial structures is disposed next to a corresponding one of the plurality of gate structures along the first lateral direction; and a common epitaxial structure disposed over the well, wherein the common epitaxial structure has the first conductive type and is in contact with the well. A first group of the plurality of epitaxial structures are each in contact with the well, and a second group of the plurality of epitaxial structures each have a bottom surface separated from the well with a corresponding dielectric layer.

In yet another aspect of the present disclosure, a method for fabricating memory devices is disclosed. The method includes forming a well in a substrate, wherein the well extends along a first lateral direction and has a first conductive type. The method includes forming an active region over the well, wherein the active region extends along the first lateral direction. The method includes forming a plurality of gate structures over the active region, wherein the plurality of gate structures extend along a second lateral direction perpendicular to the first lateral direction. The method includes forming a dielectric layer in a first portion of the well, with a second portion and a third portion of the well exposed. The method includes forming a common epitaxial structure to contact the second portion of the well, wherein the common epitaxial structure has the first conductive type. The method includes forming a first epitaxial structure separated apart from the well with the dielectric layer, wherein the first epitaxial structure has a second conductive type. The method includes forming a second epitaxial structure to contact the third portion of the well, wherein the second epitaxial structure has the second conductive type.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a well formed in a substrate and extending along a first lateral direction, wherein the well has a first conductive type;
a plurality of epitaxial structures disposed over the well, wherein the plurality of epitaxial structures have a second conductive type opposite to the first conductive type; and
a common epitaxial structure disposed over the well, wherein the common epitaxial structure has the first conductive type and is in contact the well;
wherein a first group of the plurality of epitaxial structures are each in contact with the well, and a second group of the plurality of epitaxial structures each have a bottom surface separated from the well with a corresponding dielectric layer.

2. The memory device of claim 1, further comprising:
a plurality of gate structures extending along a second lateral direction perpendicular to the first lateral direction;
wherein the plurality of gate structures and the plurality of epitaxial structures are alternately arranged with respect to one another along the first lateral direction.

3. The memory device of claim 2, further comprising:
a first interconnect structure extending along the first lateral direction, and electrically coupled to the plurality of gate structures;
a second interconnect structure extending along the first lateral direction, and electrically coupled to the common epitaxial structure; and
a plurality of third interconnect structures extending along the second lateral direction, and electrically coupled to the plurality of epitaxial structures, respectively.

4. The memory device of claim 3, wherein the first conductive type and the second conductive type are p-type and n-type, respectively, and wherein the second interconnect structure is coupled to VSS.

5. The memory device of claim 3, wherein the first conductive type and the second conductive type are n-type and p-type, respectively, and wherein the second interconnect structure is coupled to VDD.

6. The memory device of claim 1, wherein a corresponding one of the first group of the epitaxial structures and the common epitaxial structure operatively serve as a first type of diode.

7. The memory device of claim 6, wherein a corresponding one of the second group of the epitaxial structures and the common epitaxial structure operatively serve as a second second type diode.

8. The memory device of claim 7, wherein the first type of diode presents a first logic state, and the second type of diode presents a second logic state.

9. The memory device of claim 2, further comprising:
a plurality of stacks, each of which includes a plurality of semiconductor nanostructures vertically spaced from one another.

10. The memory device of claim 9, wherein each of the gate structures wraps around the semiconductor nanostructures of a corresponding one of the plurality of stacks.

11. A memory device, comprising:
a well formed in a substrate and extending along a first lateral direction, wherein the well has a first conductive type;
a plurality of epitaxial structures disposed over the well, wherein the plurality of epitaxial structures have a second conductive type opposite to the first conductive type;
a plurality of gate structures extending along a second lateral direction perpendicular to the first lateral direction, wherein each of the plurality of epitaxial structures is disposed next to a corresponding one of the plurality of gate structures along the first lateral direction; and
a common epitaxial structure disposed over the well, wherein the common epitaxial structure has the first conductive type and is in contact with the well;
wherein a first group of the plurality of epitaxial structures are each in contact with the well, and a second group of the plurality of epitaxial structures each have a bottom surface separated from the well with a corresponding dielectric layer.

12. The memory device of claim 11, further comprising:
a first interconnect structure extending along the first lateral direction, and electrically coupled to the plurality of gate structures;
a second interconnect structure extending along the first lateral direction, and electrically coupled to the common epitaxial structure; and
a plurality of third interconnect structures extending along the second lateral direction, and electrically coupled to the plurality of epitaxial structures, respectively.

13. The memory device of claim 12, wherein the first conductive type and the second conductive type are p-type and n-type, respectively, and wherein the second interconnect structure is coupled to VSS.

14. The memory device of claim 12, wherein the first conductive type and the second conductive type are n-type and p-type, respectively, and wherein the second interconnect structure is coupled to VDD.

15. The memory device of claim 11, wherein a corresponding one of the first group of the epitaxial structures and the common epitaxial structure operatively serve as a first type of diode.

16. The memory device of claim 15, wherein a corresponding one of the second group of the epitaxial structures and the common epitaxial structure operatively serve as a second type of diode.

17. The memory device of claim 16, wherein the first type of diode presents a first logic state, and the second type of diode presents a second logic state.

18. A method for forming memory devices, comprising:
forming a well in a substrate, wherein the well extends along a first lateral direction and has a first conductive type;
forming an active region over the well, wherein the active region extends along the first lateral direction;
forming a plurality of gate structures over the active region, wherein the plurality of gate structures extend along a second lateral direction perpendicular to the first lateral direction;
forming a dielectric layer in a first portion of the well, with a second portion and a third portion of the well exposed;
forming a common epitaxial structure to contact the second portion of the well, wherein the common epitaxial structure has the first conductive type;
forming a first epitaxial structure separated apart from the well with the dielectric layer, wherein the first epitaxial structure has a second conductive type; and
forming a second epitaxial structure to contact the third portion of the well, wherein the second epitaxial structure has the second conductive type.

19. The method of claim 18, wherein the first conductive type and the second conductive type are p-type and n-type, respectively, and wherein the plurality of gate structures are coupled to VSS.

20. The method of claim 18, wherein the first conductive type and the second conductive type are n-type and p-type, respectively, and wherein the plurality of gate structures are coupled to VDD.
